(19) United States
(12) Patent Application Publication
(10) Pub. No.: US 2024/0371845 A1
(43) Pub. Date: Nov. 7, 2024

(54) ELECTRONIC DEVICE

(71) Applicant: InnoLux Corporation, Miao-Li County (TW)

(72) Inventors: Yu-Jhou GONG, Miao-Li County (TW); Tsung-Han TSAI, Miao-Li County (TW); Kuan-Feng LEE, Miao-Li County (TW); Jia-Yuan CHEN, Miao-Li County (TW)

(73) Assignee: InnoLux Corporation, Miao-Li County (TW)

(21) Appl. No.: 18/628,827

(22) Filed: Apr. 8, 2024

(30) Foreign Application Priority Data
May 4, 2023 (CN) 202310490406.1

(51) Int. Cl. H01L 25/16; H01L 31/0232; H01L 33/50; H01L 33/60

(52) U.S. Cl. CPC H01L 25/167; H01L 31/02327; H01L 33/507; H01L 33/60; H01L 2224/24147; H01L 2924/12041; H01L 2924/12043; H01L 2924/1426

(57) ABSTRACT

An electronic device includes a substrate structure, an insulating layer, a semiconductor unit and a first electromagnetic signal adjusting unit. The insulating layer is disposed on the substrate structure and has a recess. The semiconductor unit is disposed in the recess. The first electromagnetic signal adjusting unit is disposed on the insulating layer and configured for adjusting an electromagnetic signal, wherein the first electromagnetic signal adjusting unit is overlapped with the semiconductor unit. In a top view of the electronic device, a first distance is between a defined center of the recess and a defined center of the semiconductor unit, a second distance is between a defined center of the first electromagnetic signal adjusting unit and the defined center of the semiconductor unit, and the first distance is greater than 0 and the second distance is less than or equal to the first distance.

### BACKGROUND OF THE DISCLOSURE

### 1. Field of the Disclosure

The present disclosure relates to an electronic device, and more particularly to an electronic device including semiconductor units.

### 2. Description of the Prior Art

Semiconductor units can be transferred to target substrates in large quantities through mass transfer technology, thereby achieving mass production. Current mass transfer technology may include a fluid transfer process, wherein the fluid transfer process achieves the effect of transferring a large amount of semiconductor units by dropping a liquid containing semiconductor units on a target substrate. However, when semiconductor units are transferred through fluid transfer process, the semiconductor units may not be disposed in order, such that the distribution of the semiconductor units may not be uniform or the electrical connection between the semiconductor units and other elements may be poor. Therefore, to improve the reliability of the semiconductor units transferred through fluid transfer process is still an important issue in the present field.

### SUMMARY OF THE DISCLOSURE

The present disclosure aims at providing an electronic device.

In some embodiments, an electronic device is provided by the present disclosure. The electronic device includes a substrate structure, an insulating layer, a semiconductor unit and a first electromagnetic signal adjusting unit. The insulating layer is disposed on the substrate structure and has a recess. The semiconductor unit is disposed in the recess. The first electromagnetic signal adjusting unit is disposed on the insulating layer and configured for adjusting an electromagnetic signal, wherein the first electromagnetic signal adjusting unit is overlapped with the semiconductor unit. In a top view of the electronic device, a first distance is between a defined center of the recess and a defined center of the semiconductor unit, a second distance is between a defined center of the first electromagnetic signal adjusting unit and the defined center of the semiconductor unit, and the first distance is greater than 0 and the second distance is less than or equal to the first distance.

In some embodiments, an electronic device is provided by the present disclosure. The electronic device includes a substrate structure, an insulating layer, an electromagnetic signal reflector, a semiconductor unit and a first electromagnetic signal adjusting unit. The insulating layer is disposed on the substrate structure and has a recess. The electromagnetic signal reflector is disposed in the recess. The semiconductor unit is disposed in the recess. The first electromagnetic signal adjusting unit is disposed on the insulating layer and configured for adjusting an electromagnetic signal, wherein the first electromagnetic signal adjusting unit is overlapped with the semiconductor unit. In a top view of the electronic device, a first distance is between a defined center of the semiconductor unit and a defined center of the recess, a second distance is between a defined center of the first electromagnetic signal adjusting unit and the defined center of the recess, and the first distance is greater than 0 and the second distance is less than or equal to the first distance.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a cross-sectional view of an electronic device according to a first embodiment of the present disclosure.

FIG. 2A to FIG. 2D schematically illustrate the transferring process of the semiconductor units of the electronic device according to the first embodiment of the present disclosure.

FIG. 3A to FIG. 3F schematically illustrate the manufacturing process of the electronic device according to the first embodiment of the present disclosure.

FIG. 3G schematically illustrates a cross-sectional view of an electronic device according to a variant embodiment of the first embodiment of the present disclosure.

FIG. 3H schematically illustrates a cross-sectional view of an electronic device according to another variant embodiment of the first embodiment of the present disclosure.

FIG. 4 shows the definition of the defined center of the first electromagnetic signal adjusting unit of the present disclosure.

FIG. 5 shows examples of the recess and the semiconductor unit of the present disclosure.

FIG. 6A schematically illustrates a top view of an electronic device according to a second embodiment of the present disclosure.

FIG. 6B schematically illustrates a top view of an electronic device according to a variant embodiment of the second embodiment of the present disclosure.

FIG. 6C schematically illustrates a top view of an electronic device according to another variant embodiment of the second embodiment of the present disclosure.

FIG. 7A schematically illustrates a top view of an electronic device according to a third embodiment of the present disclosure.

FIG. 7B schematically illustrates a top view of an electronic device according to a variant embodiment of the third embodiment of the present disclosure.

FIG. 7C schematically illustrates a top view of an electronic device according variant embodiment of the third embodiment of the present disclosure.

FIG. 8A schematically illustrates a top view of an electronic device according to a fourth embodiment of the present disclosure.

FIG. 8B schematically illustrates a cross-sectional view of an electronic device according to a variant embodiment of the fourth embodiment of the present disclosure.

FIG. 8C schematically illustrates a cross-sectional view of an electronic device according to another variant embodiment of the fourth embodiment of the present disclosure.

FIG. 9 schematically illustrates a cross-sectional view of an electronic device according to a fifth embodiment of the present disclosure.

FIG. 10 schematically illustrates a cross-sectional view of an electronic device according to a sixth embodiment of the present disclosure.

FIG. 11 schematically illustrates a cross-sectional view of an electronic device according to a seventh embodiment of the present disclosure.

FIG. 12 schematically illustrates a cross-sectional view of an electronic device according to an eighth embodiment of the present disclosure.

FIG. 13 schematically illustrates a cross-sectional view of an electronic device according to a ninth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

According to the present disclosure, the thickness, length and width may be measured through optical microscope, and the thickness or width may be measured through the cross-sectional view in the electron microscope, but not limited thereto.

In addition, any two values or directions used for comparison may have certain errors. In addition, the terms “equal to”, “equal”, “the same”, “approximately” or “substantially” are generally interpreted as being within ±20%, ±10%, ±5%, ±3%, ±2%, ±1%, or ±0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may include a display device, a sensing device, a backlight device, an antenna device, a tiled device or other suitable electronic devices, but not limited thereto. The electronic device may be a foldable electronic device, a flexible electronic device or a stretchable electronic device. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The sensing device may include biosensors, touch sensors, fingerprint sensors, optical sensors, other suitable sensors or combinations of the above sensors. The antenna device may for example include liquid crystal antenna devices or other suitable antenna devices. The tiled device may for example include tiled display devices or tiled antenna devices, but not limited thereto. The outline of the electronic device may be a rectangle, a circle, a polygon, a shape with curved edge or other suitable shapes. The electronic device may include electronic units, wherein the electronic units may include semiconductor units. The semiconductor units may include passive elements or active elements, such as capacitor, resistor, inductor, diode, transistor, sensors, integrated circuits, and the like. The diode may include a light emitting diode, a photo diode or a varactor diode. The light emitting diode may for example include an organic light emitting diode (OLED) or an in-organic light emitting diode. The in-organic light emitting diode may for example include a mini light emitting diode (mini LED), a micro light emitting diode (micro LED) or a quantum dot light emitting diode (QLED), but not limited thereto. It should be noted that the electronic device of the present disclosure may be combinations of the above-mentioned devices, but not limited thereto.

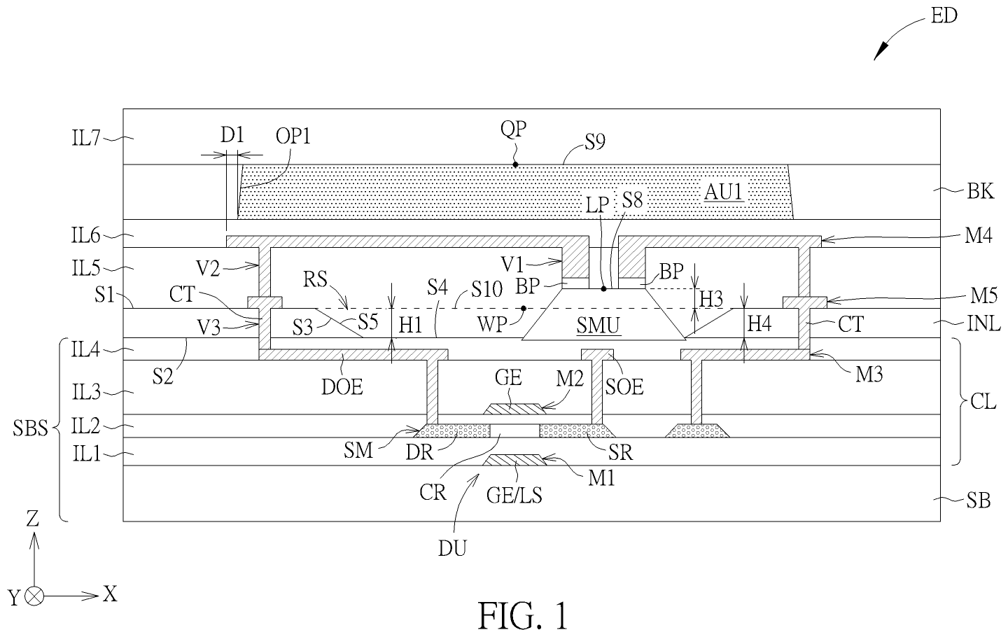

Referring to FIG. 1, FIG. 1 schematically illustrates a cross-sectional view of an electronic device according to a first embodiment of the present disclosure. According to the present disclosure, the electronic device ED may include a substrate structure SBS, an insulating layer INL, a semiconductor unit SMU and a first electromagnetic signal adjusting unit AU1. The insulating layer INL is disposed on the substrate structure SBS and has a recess RS, and the semiconductor unit SMU is disposed in the recess RS of the insulating layer INL. The first electromagnetic signal adjusting unit AU1 is disposed on the insulating layer INL and may be overlapped with the semiconductor unit SMU. Specifically, in a top view of the electronic device ED, the first electromagnetic signal adjusting unit AU1 may be overlapped with (or at least partially overlapped with) the semiconductor unit SMU. The first electromagnetic signal adjusting unit AU1 may be configured for adjusting an electromagnetic signal. The semiconductor unit SMU may emit or receive an electromagnetic signal, and the first electromagnetic signal adjusting unit AU1 may be used for adjusting the electromagnetic signal emitted from or received by the semiconductor unit SMU. The features of the layers/elements of the electronic device ED will be detailed in the following. It should be noted that the above-mentioned “top view of the electronic device ED” may represent the external view or the perspective view obtained by observing the electronic device ED in the direction opposite to the normal direction (that is, parallel to the direction Z, which will not be redundantly described) of the substrate structure SBS of the electronic device ED. In addition, the direction of the top view of the electronic device ED (that is, the top view direction) may represent the direction opposite to the direction Z. The definitions of “top view” or “top view direction” mentioned in the following may refer to the contents mentioned above, and will not be redundantly described.

The substrate structure SBS may include a base SB and a circuit layer CL disposed on the base SB. The base SB may include a rigid base or a flexible base. The rigid base for example includes glass, quartz, sapphire, ceramic, other suitable materials or combinations of the above-mentioned materials, and the flexible base for example includes polyimide (PI), polycarbonate (PC), polyethylene terephthalate (PET), other suitable materials or combinations of the above-mentioned materials, but not limited thereto. The circuit layer CL may include various kinds of wires, circuits and electronic units (such as active elements and/or passive elements) that can be applied to the electronic device ED, but not limited thereto. For example, the circuit layer CL may include a driving unit DU, wherein the driving unit DU may be electrically connected to any suitable electronic unit in the electronic device ED. For example, the driving unit DU may be electrically connected to the semiconductor unit SMU to drive the semiconductor unit SMU, but not limited thereto. The driving unit DU may for example include thin film transistor (TFT), but not limited thereto. Specifically, the circuit layer CL may include a semiconductor layer SM, a conductive layer M1, a conductive layer M2, and a conductive layer M3, wherein the driving unit DU may include the semiconductor layer SM and a gate electrode GE, the semiconductor layer SM may include a channel region CR, a source region SR and a drain region DR, and the conductive layer M2 may form the gate electrode GE of the driving unit DU. In the top view of the electronic device ED (or in the top view direction of the electronic device ED), the gate electrode GE may be overlapped with the channel region CR of the semiconductor layer SM. In such condition, the driving unit DU may for example include top gate thin film transistor, but the present embodiment is not limited thereto. The conductive layer M1 may be disposed under the semiconductor layer SM. For example, the conductive layer M1 may be disposed on the base SB and located between the semiconductor layer SM and the base SB, but not limited thereto. In some embodiments, the conductive layer M1 may form the gate electrode GE of the driving unit DU, and the driving unit DU may for example include dual gate thin film transistor. In some embodiments, the conductive layer M1 may form a light shielding element LS, wherein the light shielding element LS may be configured for reducing the influence of external light on the driving unit DU. The conductive layer M3 may be disposed on the conductive layer M2 and may form a source electrode SOE and a drain electrode DOE respectively be electrically connected to the source region SR and the drain region DR. The semiconductor layer SM may include a semiconductor material. The semiconductor material for example include silicon or metal oxides, such as low temperature polysilicon (LTPS) semiconductor, amorphous silicon (a-Si) semiconductor, or metal oxide semiconductor, and the metal oxide semiconductor may for example include low temperature polysilicon oxide (LTPO) and indium gallium zinc oxide (IGZO) semiconductor, but not limited thereto. In an embodiment, the circuit layer CL may include a plurality of driving units DU, and the driving units DU may include the semiconductor layers of different materials. For example, one of the driving units DU may include a LTPS semiconductor, and another one of the driving units DU may include a metal oxide semiconductor, but not limited thereto. The conductive layer M1, the conductive layer M2 and the conductive layer M3 may include any suitable conductive material, such as metal materials, but not limited thereto. As shown in FIG. 1, the circuit layer CL may further include an insulating layer IL1 located between the conductive layer M1 and the semiconductor layer SM, an insulating layer IL2 located between the semiconductor layer SM and the conductive layer M2, an insulating layer IL3 located between the conductive layer M2 and the conductive layer M3, and an insulating layer IL4 located on the conductive layer M3 and covering the conductive layer M3. The insulating layer IL1, the insulating layer IL2, the insulating layer IL3 and the insulating layer IL4 may include any suitable insulating material, such as organic insulating material or inorganic insulating material. The insulating layer IL1, the insulating layer IL2, the insulating layer IL3 and the insulating layer IL4 may include single-layer structure or multi-layer structure, but not limited thereto. The insulating layer IL2 may for example be the gate insulating layer in the driving unit DU. In some embodiments, the insulating layer IL1 may also serve as the gate insulating layer in the driving unit DU. It should be noted that the structure of the circuit layer CL shown in FIG. 1 is exemplary, and the present embodiment is not limited thereto.

The insulating layer INL is disposed on the circuit layer CL of the substrate structure SBS. For example, the insulating layer INL may be disposed on the insulating layer IL4 of the circuit layer CL, but not limited thereto. The insulating layer INL may include any suitable insulating material. The recess RS of the insulating layer INL may be formed by removing a portion of the insulating layer INL. In the present embodiment, the recess RS may expose a portion of the circuit layer CL, that is, the recess RS may penetrate through the insulating layer INL, but not limited thereto. In such condition, the insulating layer INL may include an upper surface S1, a lower surface S2 and a first surface S3, wherein the first surface S3 may be the side surface of the insulating layer INL and connect the upper surface S1 and the lower surface S2. In addition, the recess RS may include a bottom surface S4 and a side surface S5. The bottom surface S4 of the recess RS may be defined as the surface surrounded by the lower surface S2 of the insulating layer INL and not covered by the lower surface S2 of the insulating layer INL, but not limited thereto. The recess RS may have a height H1, wherein the height H1 may for example be defined as a vertical distance (that is, the distance in the normal direction Z of the electronic device ED) between the horizontal lines respectively passing through the bottom of the recess RS and the top of the recess RS in a cross-sectional view of the electronic device ED, but not limited thereto. In a cross-sectional view of the electronic device ED, the horizontal line passing through the top of the recess RS may correspond to a position of 0.95 times the height H4 of the insulating layer INL. The height H4 of the insulating layer INL may be defined by the distance between the upper surface S1 and the lower surface S2 of the insulating layer INL in the direction Z. Specifically, the portion of the sidewall of the recess RS from the bottom of the recess RS to a point on the sidewall of the recess RS corresponding to 0.95 times the height H4 may be defined as the side surface S5, but not limited thereto. In such condition, the height H1 of the recess RS may be the vertical distance between the bottom (that is, the bottom surface S4) of the recess RS and the top (i.e., corresponding to a position of 0.95 times the height H4) of the recess RS, that is, the height H1 may be 0.95 times the height H4. In the embodiment that the recess RS penetrate through the insulating layer INL, the bottom surface S4 of the recess RS may substantially be coplanar with the lower surface S2 of the insulating layer INL, and the side surface S5 of the recess RS may correspond to the first surface S3 of the insulating layer INL.

It should be noted that in some embodiments, the recess RS may not expose the circuit layer CL, that is, the recess RS may not penetrate through the insulating layer INL. In such condition, the insulating layer INL may further include a second surface (not shown) corresponding to the bottom surface S4 of the recess RS, the first surface S3 may connect the upper surface S1 and the second surface, and the bottom surface S4 of the recess RS may be coplanar with the second surface of the insulating layer INL. In addition, the height H1 may be defined as the distance between the horizontal lines respectively passing through the second surface of the recess RS and the top of the recess RS in the direction Z in a cross-sectional view of the electronic device ED, and the portion of the sidewall of the recess RS from the second surface of the recess RS to a point corresponding to 0.95 times the height H4 may be defined as the side surface S5 of the recess RS. Furthermore, the height H1 of the recess RS may be the distance between the second surface of the recess RS and the top of the recess RS (i.e., corresponding to a position of 0.95 times the height H4) in the direction Z. The definitions of the surfaces of the insulating layer INL and the recess RS in the following embodiments may refer to the contents above, and will not be redundantly described.

According to the present embodiment, after the recess RS is formed in the insulating layer INL, the semiconductor unit SMU may be disposed in the recess RS. Specifically, the semiconductor unit SMU may be disposed in the recess RS through fluid transfer process. The semiconductor unit SMU may include any suitable electronic unit capable of emitting, receiving or adjusting electromagnetic signal according to the type of the electronic device ED. For example, in an embodiment, the electronic device ED may include a display device, and the semiconductor unit SMU may include light emitting unit. The light emitting unit may for example include light emitting diode and may emit electromagnetic signal, but not limited thereto. In such condition, the insulating layer INL may serve as the pixel defining layer (PDL). In some embodiments, the electronic device ED may include a sensing device, and the semiconductor unit SMU may include any suitable sensing unit, such as photodiode which can receive electromagnetic signal, but not limited thereto. In some embodiments, the electronic device ED may include an antenna device, and the semiconductor unit SMU may include the electronic unit capable of receiving or transmitting electromagnetic signal.

The semiconductor unit SMU may be electrically connected to the driving unit DU in the circuit layer CL, such that the semiconductor unit SMU may be driven by the driving unit DU. Specifically, the electronic device ED may further include an insulating layer IL5 and a conductive layer M4, wherein the insulating layer IL5 may be disposed on the insulating layer INL and the semiconductor unit SMU and cover the insulating layer INL and the semiconductor unit SMU, and the conductive layer M4 may be disposed on the insulating layer IL5. The insulating layer IL5 may include vias V1, wherein the vias V1 may at least partially expose the conductive pads BP of the semiconductor unit SMU, and the conductive layer M4 may be disposed in the vias V1 to be electrically connected to the conductive pads BP, such that the semiconductor unit SMU may be electrically connected to the conductive layer M4. In addition, the insulating layer IL5 may further include vias V2, wherein the vias V2 may at least partially expose the connecting elements CT. The conductive layer M4 may be disposed in the vias V2 to be electrically connected to the connecting elements CT. The connecting elements CT may be disposed in the vias V3 of the insulating layer INL and the insulating layer IL4 and extend on the upper surface S1 of the insulating layer INL, wherein the vias V3 may at least partially expose a portion of the driving unit DU (for example, the drain electrode DOE of the driving unit DU, but not limited thereto), such that the connecting elements CT may be electrically connected to the driving units DU. Therefore, the semiconductor unit SMU may be electrically connected to the driving unit DU through the conductive pads BP, the conductive layer M4 and the connecting elements CT. The connecting elements CT may be formed of the conductive layer M5. The conductive layer M5 and the conductive layer M4 may include any suitable conductive material, such as metal materials, but not limited thereto. It should be noted that the electrical connection between the semiconductor unit SMU and the driving unit DU mentioned above is exemplary, and the present disclosure is not limited thereto. The semiconductor unit SMU may be electrically connected to the driving unit DU through any suitable way.

The first electromagnetic signal adjusting unit AU1 may include any suitable material capable of adjusting or filtering electromagnetic signal, such as quantum dot (QD) material, color filter material, fluorescent material, phosphorescent material, liquid crystal material, microlens or other suitable materials, but not limited thereto. The first electromagnetic signal adjusting unit AU1 may be disposed on the semiconductor unit SMU and overlap the semiconductor unit SMU, thereby adjusting or filtering the electromagnetic signal emitted from or received by the semiconductor unit SMU. Specifically, the electronic device ED may include a shielding structure BK disposed on the insulating layer IL5, an opening OP1 may be defined in the shielding structure BK, and the first electromagnetic signal adjusting unit AU1 may be disposed in the opening OP1. The opening OP1 of the shielding structure BK may overlap the semiconductor unit SMU, such that the first electromagnetic signal adjusting unit AU1 is overlapped with the semiconductor unit SMU. The shielding structure BK includes any suitable material reducing capable of or blocking the electromagnetic signal passing through the shielding structure BK. For example, the electronic device ED of an embodiment includes a display device, the semiconductor unit SMU includes light emitting unit, and the shielding structure BK may include light shielding materials or light absorbing materials, such as black resin, gray resin, or white resin, but not limited thereto. In such condition, the first electromagnetic signal adjusting unit AU1 may include the material capable of adjusting the wavelength and/or the color of the electromagnetic signal (that is, light) emitted from the light emitting unit, such as quantum dot material, color filter material, fluorescent material, phosphorescent material or other suitable materials. For example, the first electromagnetic signal adjusting unit AU1 may include the quantum dot material in the embodiment. In some embodiments, the electronic device ED may include an antenna device, a sensing device or devices of other types, and the first electromagnetic signal adjusting unit AU1 may include any suitable material capable of adjusting electromagnetic signal according to the use of the electronic device ED.

In addition, in the present embodiment, the edge of the conductive layer M4 may protrude from the edge of the first electromagnetic signal adjusting unit AU1 in a distance D1. The distance D1 may be defined as the distance between the outer edge of the conductive layer M4 and the outer edge of the first electromagnetic signal adjusting unit AU1 in a top view of the electronic device ED, but not limited thereto. According to the present embodiment, the distance D1 may range from 0 micrometer (μm) to 15 μm, but not limited thereto. Since the electronic device ED of the present embodiment may include the display device, the possibility that the user observes light leak when he views the electronic device ED at a large viewing angle may be reduced by making the conductive layer M4 protrude from the first electromagnetic signal adjusting unit AU1. The design of the distance mentioned above may be applied to the embodiments and variant embodiments of the present disclosure.

In addition to the elements and/or the layers mentioned above, the electronic device ED may further include an insulating layer IL6 disposed between the first electromagnetic signal adjusting unit AU1 and the insulating layer IL5 and an insulating layer IL7 disposed on the first electromagnetic signal adjusting unit AU1. In some embodiments, when the electronic device ED includes a dual-substrate structure, the insulating layer IL6 may serve as the adhesive layer between the two substrates, and the insulating layer IL7 may serve as the substrate, and the material thereof may refer to the material of the base SB mentioned above, and will not be redundantly described. In some embodiments, when the electronic device ED includes a single-substrate structure, the insulating layer IL6 may serve as the encapsulation layer, and the insulating layer IL7 may serve as the encapsulation layer and/or the optical layer. It should be noted that the structure of the electronic device ED is not limited to what is shown in FIG. 1 and may include other suitable elements and/or layers according to the demands of the design of the product.

As shown in FIG. 1, in the present embodiment, the disposition position of the semiconductor unit SMU may be biased toward (or closer to) a side of the recess RS, or in other words, the semiconductor unit SMU may be disposed to be offset from the center of the recess RS. The features of disposition way and disposition position of the semiconductor unit SMU of the present disclosure will be detailed in the following.

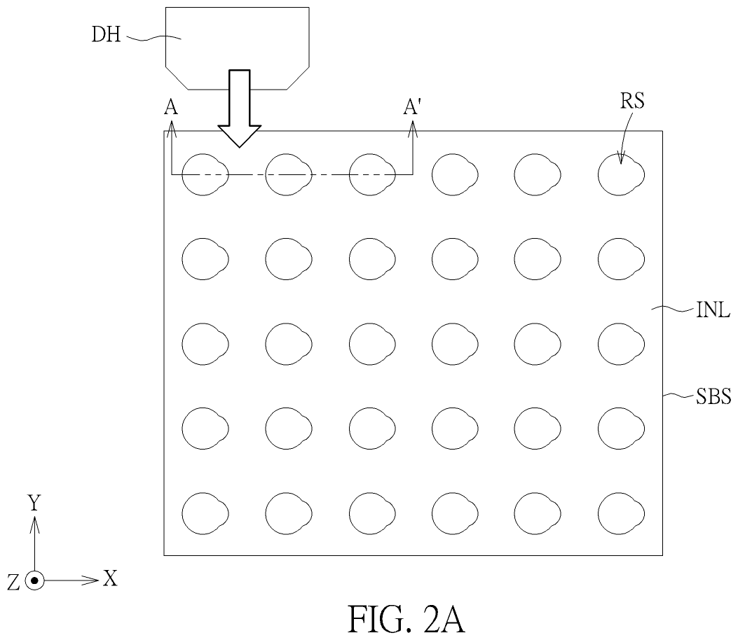

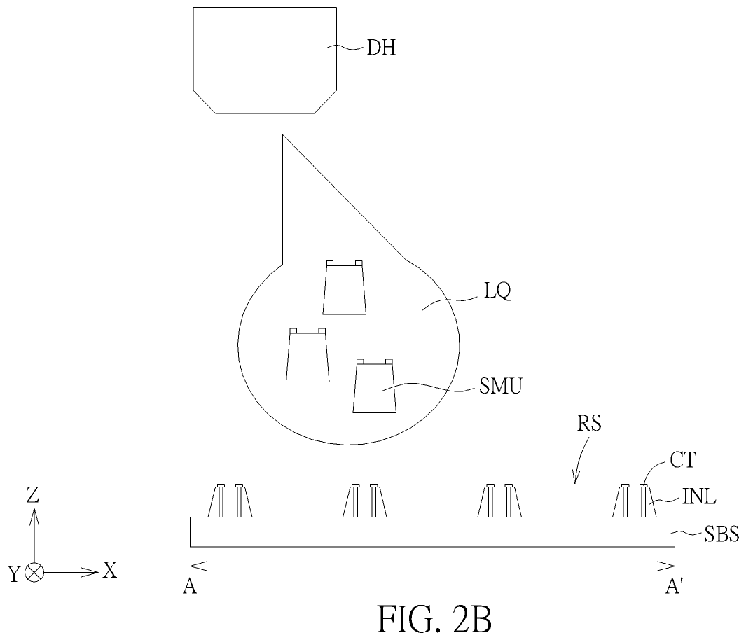

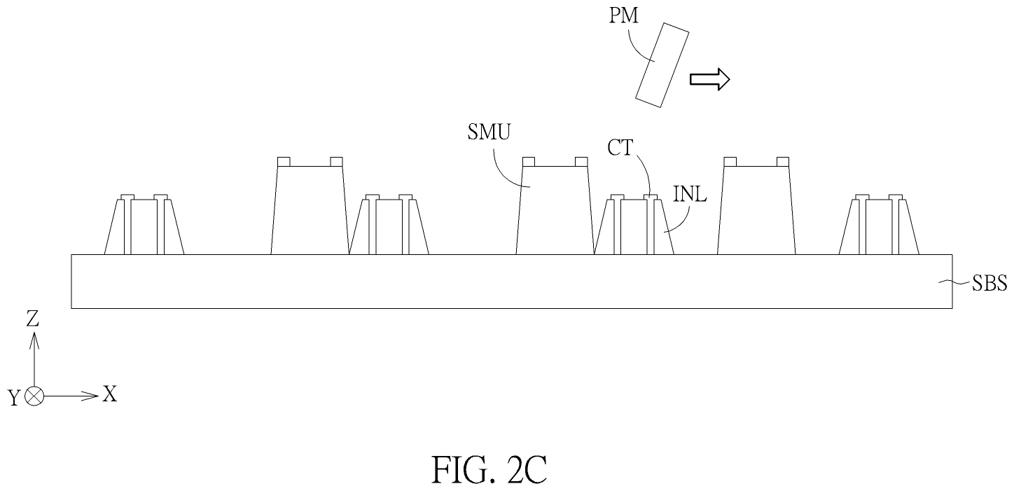

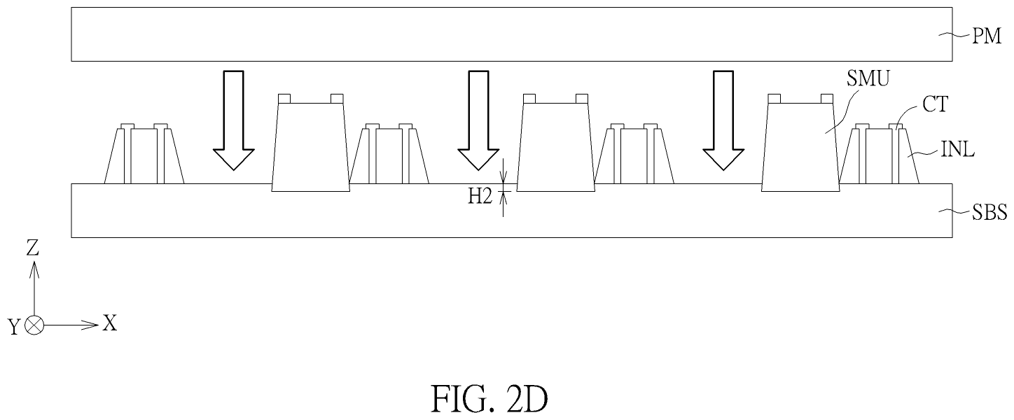

Referring to FIG. 2A to FIG. 2D, FIG. 2A to FIG. 2D schematically illustrate the transferring process of the semiconductor units of the electronic device according to the first embodiment of the present disclosure. According to the present disclosure, the semiconductor units SMU may be transferred to the target substrate through fluid transfer process. Specifically, as shown in FIG. 2A and FIG. 2B, a dropper DH may be used to drop the liquid LQ containing the semiconductor units SMU on the target substrate, wherein the “target substrate” may indicate the substrate structure SBS and the insulating layer INL having the recesses RS and disposed on the substrate structure SBS. In other words, the target substrate may include the recesses RS. The liquid LQ containing the semiconductor units SMU may be dropped at a side of the target substrate including the recesses RS. FIG. 2A shows the top view structure of the target substrate (that is, including the substrate structure SBS and the insulating layer INL having the recesses RS), and FIG. 2B shows the cross-sectional structure of the structure shown in FIG. 2A along a section line A-A′. It should be noted that in order to simplify the figure, FIG. 2B just exemplarily shows the substrate structure SBS as a single layer, and the detailed structure of the substrate structure SBS may refer to FIG. 1 and the contents mentioned above, and will not be redundantly described.

As shown in FIG. 2B, before the liquid LQ containing the semiconductor units SMU are dropped through the dropper DH, the disposition of some of the conductive lines and/or the wires on the target substrate may be completed at first. Specifically, the substrate structure SBS (including the circuit layer CL, not shown in FIG. 2B) and the insulating layer INL having the recesses RS may be formed at first, and then, the connecting elements CT (that is, the connecting elements CT shown in FIG. 1) penetrating through the insulating layer INL may be formed, wherein the connecting elements CT may be electrically connected to the driving units DU in the circuit layer CL of the substrate structure SBS. The electrical connecting way of the connecting element CT and the driving unit DU may refer to the contents mentioned above, and will not be redundantly described. After the connecting elements CT penetrating through the insulating layer INL are formed, the liquid LQ may be dropped.

After the liquid LQ is dropped, the semiconductor units SMU in the liquid LQ may enter the recesses RS. However, the positions of the semiconductor units SMU in the recesses RS are not fixed, or in other words, the semiconductor units SMU may be distributed randomly. According to the present disclosure, after the liquid LQ is dropped, a pressing module PM may move along a direction parallel to the surface of the target substrate and pressurize the semiconductor units SMU. For example, as shown in FIG. 2C, the pressing module PM may move toward the direction X and pressurize the semiconductor units SMU, but not limited thereto. In some embodiments, the pressing module PM may move toward the direction Y and pressurize the semiconductor units SMU. When the pressing module PM pressurizes the semiconductor units SMU toward a direction parallel to the surface of the target substrate, the semiconductor units SMU may move toward the direction, thereby being biased toward (or closer to) the sides of the recesses RS. Therefore, the semiconductor units SMU may be disposed in specific region or at specific position in the recesses RS, or in other words, the disposition positions of the semiconductor units SMU in the recesses RS may be in order. For example, as shown in FIG. 2C, the two semiconductor units SMU located at the left side of the pressing module PM have been moved to the right sides of the recesses RS due to being affected by the pressing module PM, and the semiconductor unit SMU located at the right side of the pressing module PM has not been affected by the pressing module PM to be moved to the right side of the recess RS.

In the present embodiment, the recess RS may have any suitable shape to help the disposition of the semiconductor units SMU at specific region or specific position in the recesses RS, but not limited thereto. For example, as shown in FIG. 2A, in the top view of the substrate structure SBS, the right side of the recess RS may have a protruded shape, and therefore, it is easily to make the semiconductor unit SMU located at the right side of the recess RS after the semiconductor unit SMU is affected by the pressing module PM and moves toward right (for example, the semiconductor unit SMU may be limited through the recess RS having the shape described above), but not limited thereto.

Referring to FIG. 1 as well, in the present embodiment, the height of the semiconductor unit SMU may be greater than the height of the insulating layer INL, that is, the semiconductor unit SMU may be protruded from the insulating layer INL. The height difference between the semiconductor unit SMU and the insulating layer INL may be the height H3, wherein the height H3 may be defined as the distance between the upper surface S8 of the semiconductor unit SMU and the upper surface S1 of the insulating layer INL, but not limited thereto. According to the present embodiment, the height difference between the semiconductor unit SMU and the insulating layer INL (that is, the height H3) may be at least half of the height H4 of the insulating layer INL. In other words, the height H3 and the height H4 may satisfy the relation of H3≥0.5*H4. Through the above-mentioned design, the possibility that the semiconductor units SMU are not pushed by the pressing module PM may be reduced.

After that, as shown in FIG. 2D, the pressing module PM may move toward the surface of the target substrate (that is, toward the direction −Z) to pressurize the semiconductor units SMU, such that the semiconductor units SMU may be pressed downward into the substrate structure SBS, thereby finishing the transferring process of the semiconductor units SMU. Referring to FIG. 1 and FIG. 2D, after the semiconductor units SMU are pressurized through the pressing module PM, the semiconductor units SMU may sink into the substrate structure SBS or the insulating layer IL4 of the circuit layer CL, but not limited thereto. Therefore, the possibility that the semiconductor units SMU are moved due to being affected by other external force in the subsequent processes may be reduced. According to the present embodiment, the portion of the semiconductor unit SMU sinking or embedded into the substrate structure SBS may have a depth H2, wherein the depth H2 may range from 0.01 micrometers (μm) to 3 μm, but not limited thereto. The depth H2 may represent the sinking depth of the semiconductor unit SMU.

Through the above-mentioned processes, the semiconductor units SMU may be located at a same region or a same position in the recesses RS, such that the condition that the semiconductor units SMU are distributed randomly may be reduced. Therefore, the performance of the electronic device ED may be improved. For example, the electronic device ED in an embodiment may include a display device, and the semiconductor units SMU may include light emitting units, but not limited thereto. In such condition, the light emitting units in the electronic device ED may be distributed uniformly, and the condition that the display effect of the electronic device ED are effected due to uneven brightness may be reduced.

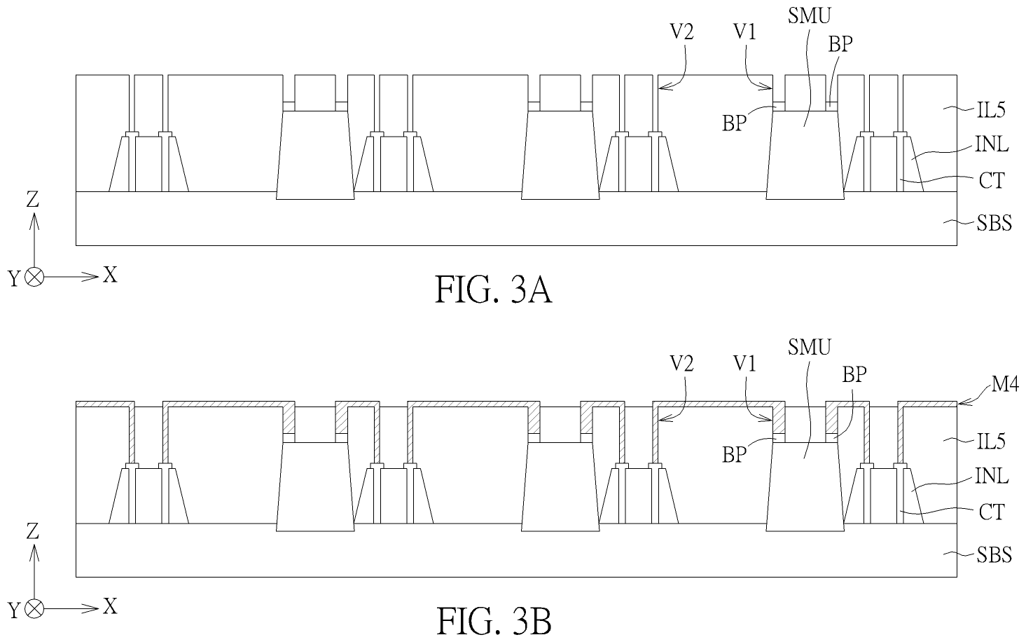

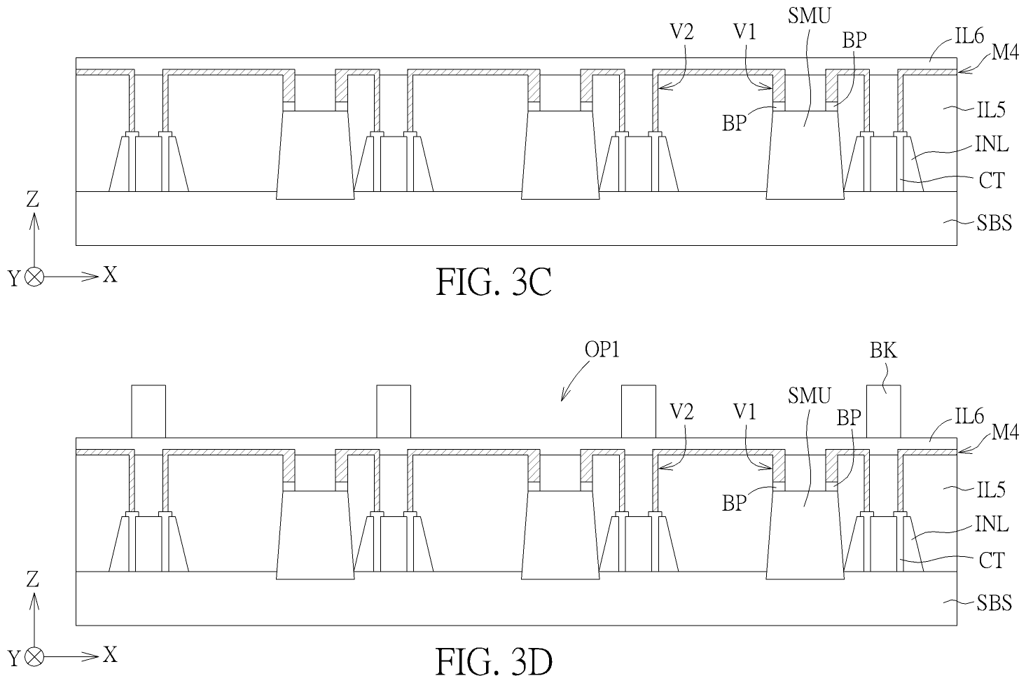

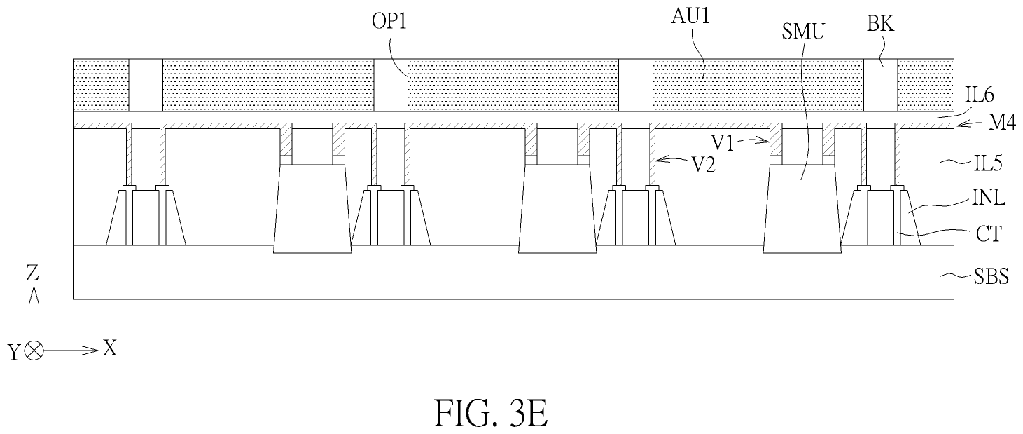

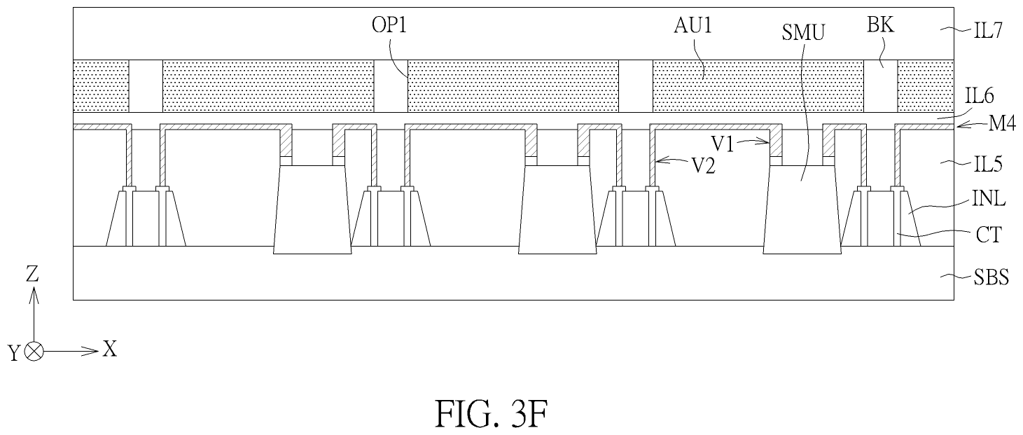

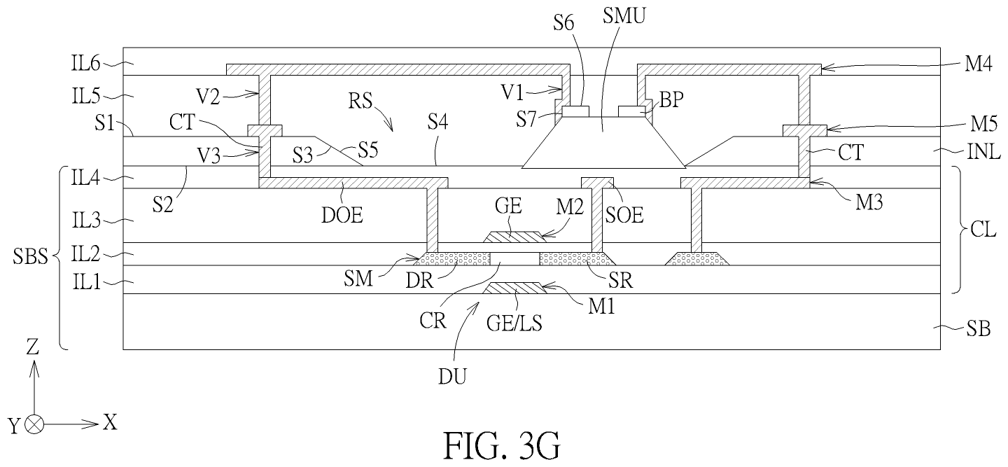

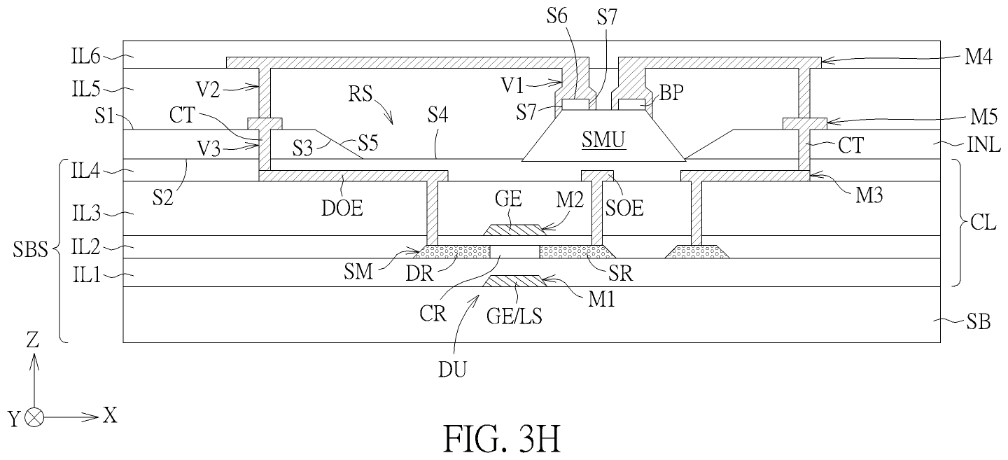

Referring to FIG. 3A to FIG. 3F, FIG. 3A to FIG. 3F schematically illustrate the manufacturing process of the electronic device according to the first embodiment of the present disclosure. As shown in FIG. 3A, after the transferring process of the semiconductor units SMU mentioned above are completed, the insulating layer IL5 may be disposed on the insulating layer INL and the semiconductor units SMU. After that, the insulating layer IL5 may be patterned to form the vias V1 and the vias V2. After that, as shown in FIG. 3B, the patterned conductive layer M4 may be formed on the insulating layer IL5, wherein the conductive layer M4 may include a plurality of conductive elements respectively be disposed in the vias V1 and the vias V2 to be electrically connected to the semiconductor units SMU and the connecting elements CT. According to the present disclosure, since the semiconductor units SMU may substantially be disposed at a same region or a same position in different recesses RS, the poor bonding between the conductive pads BP and the conductive layer M4 may be reduced under the design of fixed-position bonding. Specifically, when the semiconductor units SMU are disposed randomly, the design of fixing the position of the conductive layer M4 will cause some semiconductor units SMU to be unable to be electrically connected to the conductive layer M4, or the bonding between the semiconductor unit SMU and the conductive layer M4 may be poor. However, since the semiconductor units SMU may be disposed orderly at a specific region or a specific position in the recesses RS in the present disclosure, the bonding positions between the conductive pads BP and the conductive layer M4 may be fixed, thereby simplifying the manufacturing process and/or improving the yield of the electronic device ED.

After that, as shown in FIG. 3C, the insulating layer IL6 may be disposed on the conductive layer M4, wherein the insulating layer IL6 may cover the conductive layer M4. After that, as shown in FIG. 3D, the shielding structure BK may be disposed on the insulating layer IL6, wherein the shielding structure BK may include the openings OP1. Specifically, an entire layer of the shielding structure BK may be formed on the insulating layer IL6 at first, and a portion of the shielding structure BK may be removed through a patterning process to form the openings OP1. In the top view direction of the substrate structure SBS, the shielding structure BK may not be overlapped with the semiconductor units SMU, and the openings OP1 may be overlapped with the semiconductor units SMU. For example, the size of the opening OP1 may be greater than the size of the semiconductor unit SMU, but not limited thereto. After that, as shown in FIG. 3E, the first electromagnetic signal adjusting units AU1 may be disposed on the insulating layer IL6, wherein the first electromagnetic signal adjusting units AU1 may be disposed in the openings OP1 of the shielding structure BK and be overlapped with the semiconductor units SMU. After that, as shown in FIG. 3F, the insulating layer IL7 may be disposed on the shielding structure BK and the first electromagnetic signal adjusting units AU1, thereby forming the electronic device ED.

It should be noted that the manufacturing process of the electronic device ED mentioned above is exemplary, and the present disclosure is not limited thereto. In some embodiments, the shielding structure BK and the first electromagnetic signal adjusting units AU1 may be formed on the insulating layer IL7 to form an adjusting unit structure in other processes, and the adjusting unit structure may be adhered to the structure shown in FIG. 3B or FIG. 3C through the insulating layer IL6 to form the electronic device ED.

Referring to FIG. 3G and FIG. 3H, FIG. 3G schematically illustrates a cross-sectional view of an electronic device according to a variant embodiment of the first embodiment of the present disclosure, and FIG. 3H schematically illustrates a cross-sectional view of an electronic device according to another variant embodiment of the first embodiment of the present disclosure. One of the main differences between the electronic device ED shown in FIG. 3G and FIG. 3H and the electronic device ED shown in FIG. 1 is the electrical connecting way between the conductive layer M4 and the semiconductor unit SMU. In an embodiment, as shown in FIG. 3G, the conductive layer M4 of the electronic device ED may be disposed in the vias V1 and be electrically connected to the conductive pads BP, wherein the conductive layer M4 may contact a portion of the upper surface S6 of the conductive pad BP and the side surface S7 of the conductive pads BP. In other words, compared with the structure shown in FIG. 1, the structure shown in FIG. 3G may have a narrow-wire design, or the width of the via V1 shown in FIG. 3G may be less than the width of the via V1 shown in FIG. 1. In an embodiment, as shown in FIG. 3H, the conductive layer M4 of the electronic device ED may be disposed in the vias V1 and be electrically connected to the conductive pads BP, wherein the conductive layer M4 may contact the upper surface S6 of the conductive pad BP and two opposite side surfaces S7 of the conductive pad BP. In other words, compared with the structure shown in FIG. 1, the structure shown in FIG. 3H may have a wide-wire design, or the width of the via V1 shown in FIG. 3H may be greater than the width of the via V1 shown in FIG. 1. The design of the wire mentioned above may be applied to each of the embodiments and variant embodiments of the present disclosure, and will not be redundantly described.

According to the present disclosure, the recess RS, the semiconductor unit SMU and the first electromagnetic signal adjusting unit AU1 may respectively have a defined center. Specifically, the defined centers of the recess RS, the semiconductor unit SMU and the first electromagnetic signal adjusting unit AU1 may be defined respectively according to the shapes thereof. The definition of the defined centers of the recess RS, the semiconductor unit SMU and the first electromagnetic signal adjusting unit AU1 will be detailed in the following.

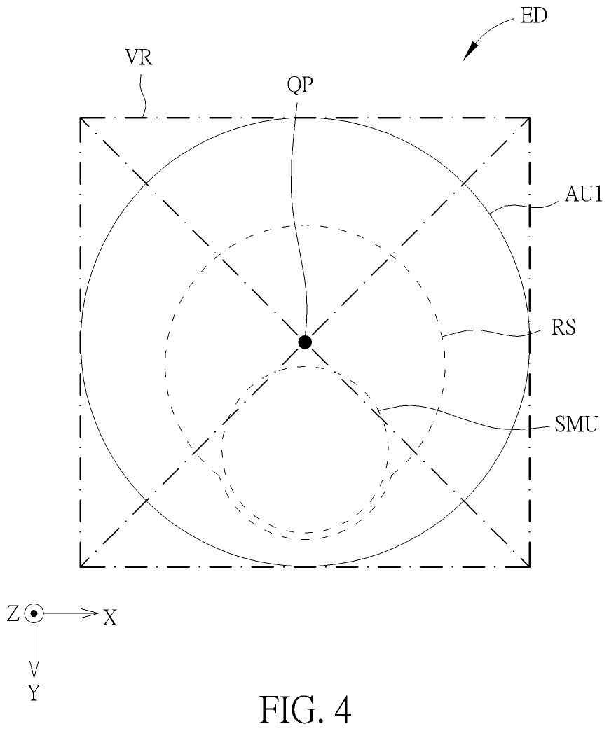

Referring to FIG. 4, FIG. 4 shows the definition of the defined center of the first electromagnetic signal adjusting unit of the present disclosure. Specifically, FIG. 4 shows the definition of the defined center of the first electromagnetic signal adjusting unit AU1 in a top view of the first electromagnetic signal adjusting unit AU1. In detail, in the top view of the first electromagnetic signal adjusting unit AU1, the center of a minimum virtual rectangle surrounding the first electromagnetic signal adjusting unit AU1 may be defined as the defined center of the first electromagnetic signal adjusting unit AU1. For example, as shown in FIG. 4, after the shape of the first electromagnetic signal adjusting unit AU1 is confirmed, the minimum virtual rectangle VR surrounding the first electromagnetic signal adjusting unit AU1 may be drawn at first, and then, two diagonals of the minimum virtual rectangle VR may be drawn, wherein the intersection of the two diagonals may be defined as the defined center QP of the first electromagnetic signal adjusting unit AU1. The first electromagnetic signal adjusting unit AU1 may include any suitable shape in the top view thereof, according to the design of the product. For example, the first electromagnetic signal adjusting unit AU1 shown in FIG. 4 may be circular in the top view thereof, but not limited thereto. In some embodiments, the shape of the first electromagnetic signal adjusting unit AU1 may be a rectangle, a trapezoid, a rhombus, a polygon or an irregular shape in the top view thereof.

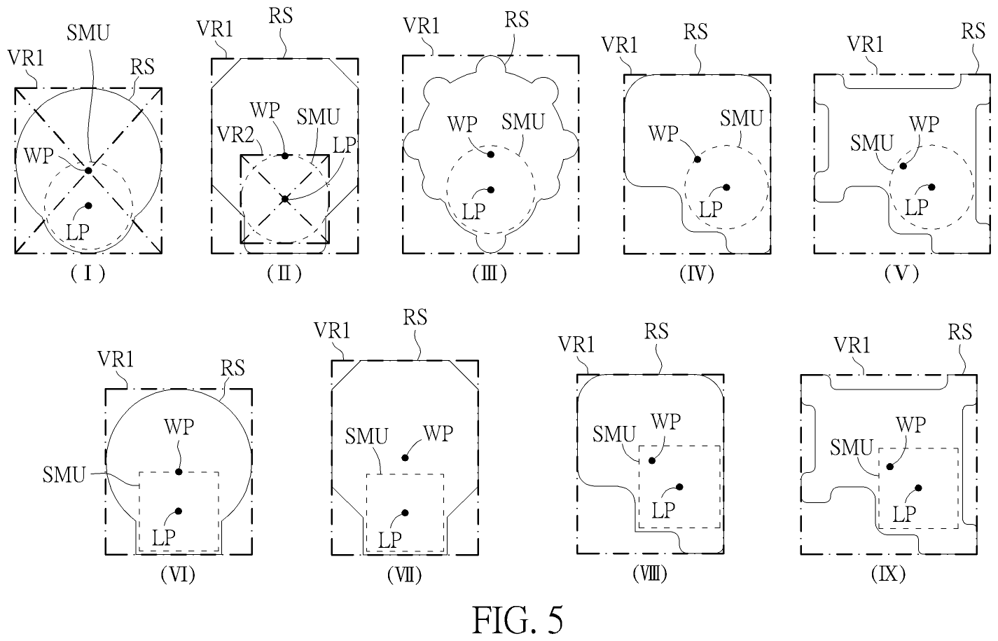

Referring to FIG. 5, FIG. 5 shows examples of the recess and the semiconductor unit of the present disclosure. FIG. 5 shows the definitions of the defined centers of the recesses RS in the top view thereof and the defined centers of the semiconductor units SMU in the top view thereof. The definitions of the defined center WP of the recess RS and the defined center LP of the semiconductor unit SMU may be similar to the definition of the defined center QP of the first electromagnetic signal adjusting unit AU1. In detail, as shown in example (I), in the top view of the recess RS, after the shape of the recess RS is confirmed, a minimum virtual rectangle VR1 surrounding the recess RS may be drawn, and the intersection of the two diagonals of the minimum virtual rectangle VR1 may be defined as the defined center WP of the recess RS. The defined centers WP of the recesses RS shown in example (II) to example (IX) may be defined in the same way, and will not be redundantly described. In addition, as shown in example (II), in the top view of the semiconductor unit SMU, after the shape of the semiconductor unit SMU is confirmed, a minimum virtual rectangle VR2 surrounding the semiconductor unit SMU may be drawn, and the intersection of the two diagonals of the minimum virtual rectangle VR2 may be defined as the defined center LP of the semiconductor unit SMU. The defined centers LP of the semiconductor units SMU shown in example (I) and example (III) to example (IX) may be defined in the same way, and will not be redundantly described. The semiconductor unit SMU may include any suitable shape in the top view thereof, such as circle, rectangle or other suitable shape. For example, in example (I) to example (V), the semiconductor units SMU may be circular in top views thereof, and in example (VI) to example (IX), the semiconductor units SMU may be rectangular in top views thereof, but not limited thereto. The recess RS may have any suitable shape capable of containing the semiconductor unit SMU or facilitating the disposition of the semiconductor unit SMU at one side of the recess RS in the top view of the recess RS. Example (I) to example (IX) shows examples of the top view structure of the recess RS, such that the semiconductor unit SMU may be disposed at one side of the recess RS, but the present disclosure is not limited thereto.

Since the first electromagnetic signal adjusting unit AU1 is disposed on the recess RS and the semiconductor unit SMU, in order to define the defined center QP, the defined center WP and the defined center LP, a laser machine (or other suitable machines) may be used to make welding points at the edge of the first electromagnetic signal adjusting unit AU1, for example, at least four welding points may be made at the edge of the first electromagnetic signal adjusting unit AU1, but not limited thereto. After that, the first electromagnetic signal adjusting unit AU1 may be peeled to expose the recess RS and the semiconductor unit SMU. After that, the minimum virtual rectangle surrounding the first electromagnetic signal adjusting unit AU1 may be drawn by an optical microscope through the previously left welding points of the first electromagnetic signal adjusting unit AU1, thereby finding the defined center QP. At the same time, the minimum virtual rectangles respectively surrounding the recess RS and the semiconductor unit SMU may be drawn to find the defined center WP of the recess RS and the defined center LP of the semiconductor unit SMU. Therefore, the defined center QP, the defined center WP and the defined center LP may be defined. It should be noted that the defining method mentioned above is exemplary, and the present disclosure is not limited thereto.

In an embodiment, the electronic device ED may include a display device, the semiconductor unit SMU may include a light emitting unit, and the first electromagnetic signal adjusting unit AU1 may include a light adjusting unit. In such condition, the defined center LP of the semiconductor unit SMU may be the defined center of the light emitting unit, and the defined center QP of the first electromagnetic signal adjusting unit AU1 may be the defined center of the light adjusting unit, but not limited thereto. In some embodiments, the semiconductor unit SMU and the first electromagnetic signal adjusting unit AU1 may respectively include other suitable elements according to the type of the electronic device ED, and the defined center LP of the semiconductor unit SMU and the defined center QP of the first electromagnetic signal adjusting unit AU1 may be regarded as the defined centers of those elements.

Return to FIG. 1, in some embodiments, the defined centers of the first electromagnetic signal adjusting unit AU1, the recess RS and the semiconductor unit SMU may be defined in the cross-sectional view of the electronic device ED. Specifically, in the cross-sectional view of the electronic device ED, the midpoint of the upper surface S9 of the first electromagnetic signal adjusting unit AU1 may be defined as the defined center QP of the first electromagnetic signal adjusting unit AU1, and the midpoint of the upper surface S10 of the recess RS may be defined as the defined center WP of the recess RS, but not limited thereto. In addition, in the cross-sectional view of the electronic device ED, the midpoint of one of the upper surface and the lower surface of the semiconductor unit SMU having a lower area may be defined as the defined center LP of the semiconductor unit SMU. For example, the midpoint of the upper surface S8 of the semiconductor unit SMU shown in FIG. 1 may be defined as the defined center LP of the semiconductor unit SMU. It should be noted that the definition mentioned above is exemplary, and the present disclosure is not limited thereto.

The relation between the positions of the defined center QP of the first electromagnetic signal adjusting unit AU1, the defined center LP of the semiconductor unit SMU and the defined center WP of the recess RS will be detailed in the following by taking the display device as an example of the electronic device ED. In such condition, the first electromagnetic signal adjusting unit AU1 may include the light adjusting unit QD, and the semiconductor unit SMU may include the light emitting unit LU. It should be noted that the electronic device ED is not limited to the display device and may include any suitable device in other embodiments, such as an antenna device, a sensing device, and the like.

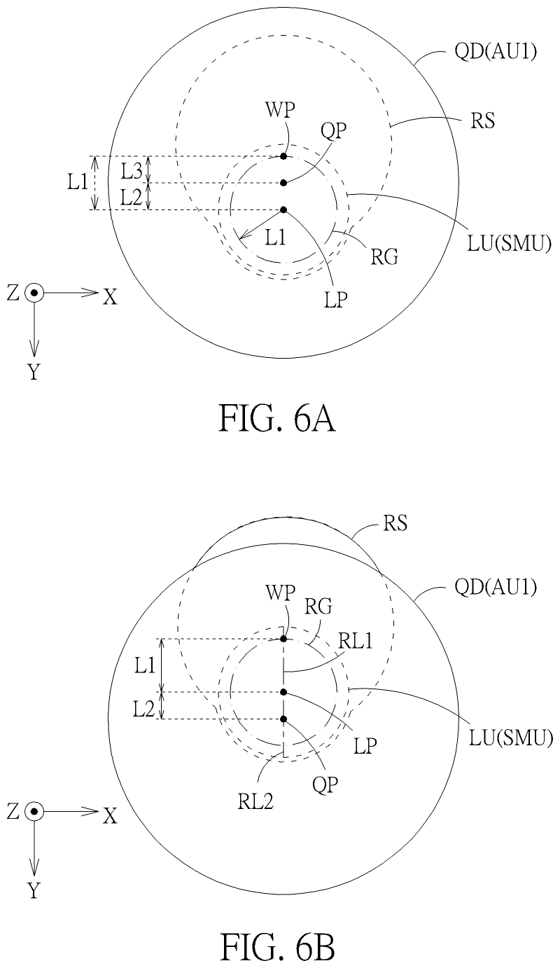

Referring to FIG. 6A, FIG. 6A schematically illustrates a top view of an electronic device according to a second embodiment of the present disclosure. According to the present embodiment, the disposition position of the first electromagnetic signal adjusting unit AU1 (that is, the light adjusting unit QD) may be determined by considering the semiconductor unit SMU (that is, the light emitting unit LU) as the main light emitting source. Since the light emitting unit LU is regarded as the main light emitting source, in the top view of the electronic device ED, the light adjusting unit QD may cover the light emitting unit LU, or the light adjusting unit QD may overlap the light emitting unit LU, such that the light emitted from the light emitting unit LU may pass through the light adjusting unit QD. Therefore, the light adjusting unit QD may receive the light emitted from the light emitting unit LU uniformly, thereby improving the display effect of the electronic device ED.

Therefore, in the present second embodiment, the first electromagnetic signal adjusting unit AU1 may be disposed on the semiconductor unit SMU, such that the defined center QP of the first electromagnetic signal adjusting unit AU1 may be corresponding to or adjacent to the defined center LP of the semiconductor unit SMU. Specifically, as shown in FIG. 6A, since the semiconductor unit SMU may be disposed at one side of the recess RS, or the semiconductor unit SMU may be disposed to be offset from the defined center WP of the recess RS, a distance L1 may be between the defined center LP of the semiconductor unit SMU and the defined center WP of the recess RS in the top view of the electronic device ED, wherein the distance L1 may be greater than 0 micrometer. A circular region RG may be drawn by taking the defined center LP as the center of a circle and the distance L1 as the radius of the circle, wherein the defined center QP of the first electromagnetic signal adjusting unit AU1 may be located at any position in the circular region RG. In other words, the disposition position of the first electromagnetic signal adjusting unit AU1 may be designed, such that the defined center QP of the first electromagnetic signal adjusting unit AU1 is located in the circular region RG. In such condition, a distance L2 may be between the defined center QP of the first electromagnetic signal adjusting unit AU1 and the defined center LP of the semiconductor unit SMU in the top view of the electronic device ED, wherein the distance L2 may be greater than or equal to 0 micrometer and less than or equal to the distance L1. In some other embodiments of the second embodiment, the distance L2 may be 0 micrometer, that is, the defined center QP may coincide with the defined center LP. Through the above-mentioned design, the area of the first electromagnetic signal adjusting unit AU1 overlapped with the semiconductor unit SMU or the proportion of the first electromagnetic signal adjusting unit AU1 overlapped with the semiconductor unit SMU may increase under the condition that the first electromagnetic signal adjusting unit AU1 overlaps the semiconductor unit SMU, thereby improving the light emitting efficiency of the electronic device ED or reducing the size of the first electromagnetic signal adjusting unit AU1. “The size of the first electromagnetic signal adjusting unit AU1” mentioned above may be the area of the first electromagnetic signal adjusting unit AU1, but not limited thereto.

In the present second embodiment, as shown in FIG. 6A, the defined center QP of the first electromagnetic signal adjusting unit AU1 may be located between the defined center LP of the semiconductor unit SMU and the defined center WP of the recess RS, but not limited thereto. In such condition, a distance L3 may be between the defined center QP of the first electromagnetic signal adjusting unit AU1 and the defined center WP of the recess RS, wherein the distance L3 may be greater than 0 micrometer and less than or equal to the distance L1. Therefore, the light emitting efficiency of the electronic device ED may be improved.

In addition, as shown in FIG. 6A, in the top view of the electronic device ED, the first electromagnetic signal adjusting unit AU1 may cover the recess RS, or in other words, the first electromagnetic signal adjusting unit AU1 may overlap the recess RS, but the present second embodiment is not limited thereto. In some other embodiments of the second embodiment, the first electromagnetic signal adjusting unit AU1 may partially cover the recess RS. In such condition, the size of the first electromagnetic signal adjusting unit AU1 may be reduced.

Referring to FIG. 6B, FIG. 6B schematically illustrates a top view of an electronic device according to a variant embodiment of the second embodiment of the present disclosure. The defined center QP of the first electromagnetic signal adjusting unit AU1 of the present variant embodiment may be located in any position in the circular region RG. In the present variant embodiment, as shown in FIG. 6B, the defined center QP of the first electromagnetic signal adjusting unit AU1 may be located at a side of the defined center LP of the semiconductor unit SMU opposite to the defined center WP of the recess RS, that is, the defined center LP may be located between the defined center WP and the defined center QP. Since the distance L2 is less than or equal to the distance L1, the defined center QP may be closer to the defined center LP compared with the defined center WP, but not limited thereto. In addition, as shown in FIG. 6B, in the top view of the electronic device ED, a portion of the recess RS may overlap the first electromagnetic signal adjusting unit AU1 (or the light adjusting unit QD), or in other words, the first electromagnetic signal adjusting unit AU1 may cover a portion of the recess RS, but the present variant embodiment is not limited thereto. In some embodiments, the first electromagnetic signal adjusting unit AU1 may completely cover the recess RS.

Referring to FIG. 6C, FIG. 6C schematically illustrates a top view of an electronic device according to another variant embodiment of the second embodiment of the present disclosure. As shown in FIG. 6C, in the top view of the electronic device ED, a first reference line RL1 may pass through the defined center WP of the recess RS and the defined center LP of the semiconductor unit SMU, and a second reference line RL2 may pass through the defined center QP of the first electromagnetic signal adjusting unit AU1 and the defined center LP of the semiconductor unit SMU, wherein an acute angle θ1 may be included between the first reference line RL1 and the second reference line RL2. Specifically, the first reference line RL1 and the second reference line RL2 may be defined according to the positions of the defined center WP, the defined center LP and the defined center QP, and the acute angle among the included angles between the first reference line RL1 and the second reference line RL2 is the acute angle θ1. According to the present variant embodiment, the acute angle θ1 may be greater than or equal to 0 degree and less than or equal to 45 degrees (that is, 0°≤θ1≤45°). When the acute angle θ1 is 0 degree, the defined center QP may be on the same straight line as the defined center WP and the defined center LP, and the defined center QP may be located between the defined center WP and the defined center LP (as shown in FIG. 6A) or located at a side of the defined center LP opposite to the defined center WP (as shown in FIG. 6B). For example, FIG. 6B shows the condition that the acute angle θ1 between the first reference line RL1 and the second reference line RL2 is 0 degree. When the acute angle θ1 is greater than 0 degree, the defined center QP is not located on the first reference line RL1. According to the range of the acute angle θ1 mentioned above, the defined center QP of the first electromagnetic signal adjusting unit AU1 of the present variant embodiment may be located in a region RG′, wherein the region RG′ may be defined by the circular region RG and two reference lines which pass through the defined center LP and respectively have the acute angle θ1 of 45 degrees (the maximum of the acute angle θ1) with the first reference line RL1. The definition of the circular region RG may refer to the contents mentioned above, and will not be redundantly described. For example, when the acute angle θ1 shown in FIG. 6C is 45 degrees, the two reference lines passing through the defined center LP and respectively having the acute angle θ1 of 45 degrees with the first reference line RL1 may be the second reference line RL2 and the second reference line RL2′ shown in FIG. 6C, and the region RG′ may include the region enclosed by the first reference line RL1 and the second reference line RL2 in the circular region RG and the region enclosed by the first reference line RL1 and the second reference line RL2′ in the circular region RG. In other words, in the present variant embodiment, the first electromagnetic signal adjusting unit AU1 may be disposed on the semiconductor unit SMU, such that the defined center QP may be located in the region RG′.

In some other embodiments of the second embodiment, the acute angle θ1 between the first reference line RL1 and the second reference line RL2 may be greater than or equal to 0 degree and less than or equal to 25 degrees (that is, 0°≤θ1≤25°). In such condition, the region RG′ may be defined by the circular region RG and the two reference lines which respectively have the acute angle θ1 of 25 degrees with the first reference line RL1, and the defined center QP may be located in the region RG′. By making the acute angle θ1 located in the above-mentioned region, the area of the first electromagnetic signal adjusting unit AU1 overlapped with the semiconductor unit SMU or the proportion of the first electromagnetic signal adjusting unit AU1 overlapped with the semiconductor unit SMU may increase under the condition that the first electromagnetic signal adjusting unit AU1 overlaps the semiconductor unit SMU, thereby improving the light emitting efficiency of the electronic device ED or reducing the size of the first electromagnetic signal adjusting unit AU1.

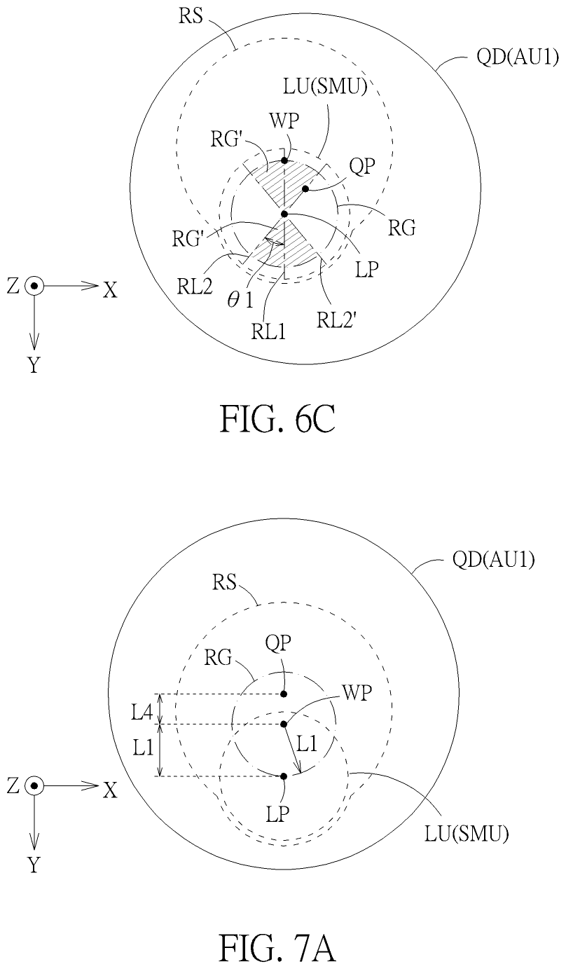

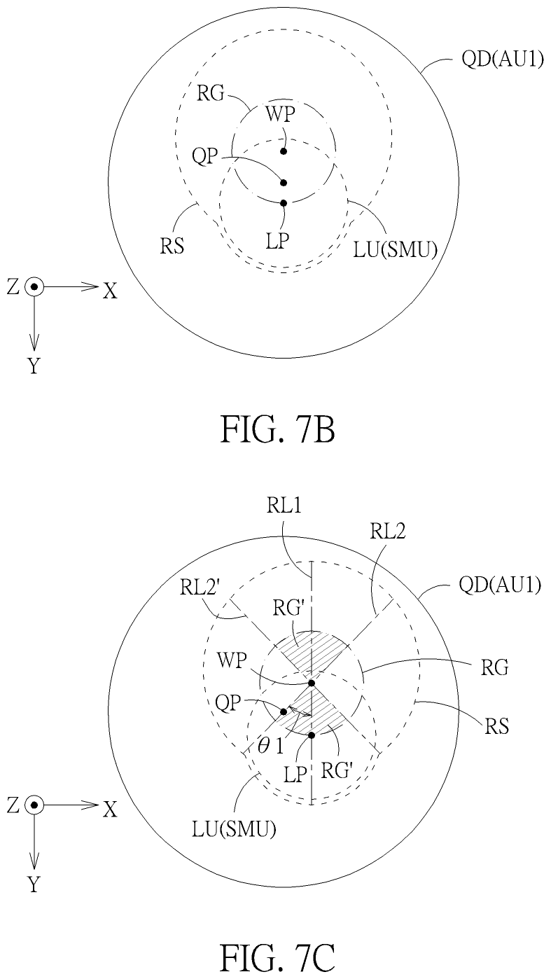

Referring to FIG. 7A and FIG. 7B, FIG. 7A schematically illustrates a top view of an electronic device according to a third embodiment of the present disclosure, and FIG. 7B schematically illustrates a top view of an electronic device according to a variant embodiment of the third embodiment of the present disclosure. According to the present third embodiment, the disposition position of the first electromagnetic signal adjusting unit AU1 (that is, the light adjusting unit QD) may be determined by considering the recess RS as the main light emitting source. Since the recess RS is considered as the main light emitting source, in the top view of the electronic device ED, the light adjusting unit QD may cover the recess RS, or the light adjusting unit QD may overlap the recess RS, such that the light adjusting unit QD may receive the light emitted from the recess RS uniformly.

According to the above-mentioned condition, in the present third embodiment, the first electromagnetic signal adjusting unit AU1 may be disposed on the semiconductor unit SMU, such that the defined center QP of the first electromagnetic signal adjusting unit AU1 may correspond to or be adjacent to the defined center WP of the recess RS. Specifically, in the top view of the electronic device ED, a distance L1 may be between the defined center LP of the semiconductor unit SMU and the defined center WP of the recess RS. As shown in FIG. 7A, a circular region RG may be drawn by taking the defined center WP as the center of a circle and the distance L1 as the radius of the circle, wherein the defined center QP of the first electromagnetic signal adjusting unit AU1 may be located at any position in the circular region RG. In other words, the disposition position of the first electromagnetic signal adjusting unit AU1 may be designed, such that the defined center QP of the first electromagnetic signal adjusting unit AU1 is located in the circular region RG. In such condition, a distance L4 may be between the defined center QP of the first electromagnetic signal adjusting unit AU1 and the defined center WP of the recess RS in the top view of the electronic device ED, wherein the distance L4 may be greater than or equal to 0 micrometer and less than or equal to the distance L1. In some other embodiments of the third embodiment, the distance L4 may be 0 micrometer, that is, the defined center QP may coincide with the defined center WP. In the present third embodiment, as shown in FIG. 7A, the defined center QP of the first electromagnetic signal adjusting unit AU1 may be located at a side of the defined center WP of the recess RS opposite to the defined center LP of the semiconductor unit SMU, that is, the defined center WP may be located between the defined center QP and the defined center LP, but not limited thereto. In some other embodiments of the third embodiment, as shown in FIG. 7B, the defined center QP of the first electromagnetic signal adjusting unit AU1 may be located between the defined center WP of the recess RS and the defined center LP of the semiconductor unit SMU. Through the above-mentioned design, the area of the first electromagnetic signal adjusting unit AU1 overlapped with the recess RS or the proportion of the first electromagnetic signal adjusting unit AU1 overlapped with the recess RS may increase under the condition that the first electromagnetic signal adjusting unit AU1 overlaps the recess RS, thereby improving the light emitting efficiency of the electronic device ED. In addition, since the first electromagnetic signal adjusting unit AU1 may overlap the recess RS, and the semiconductor unit SMU is disposed in the recess RS, the first electromagnetic signal adjusting unit AU1 may overlap the semiconductor unit SMU.

Referring to FIG. 7C, FIG. 7C schematically illustrates a top view of an electronic device according to another variant embodiment of the third embodiment of the present disclosure. As shown in FIG. 7C, in the top view of the electronic device ED, the first reference line RL1 may pass through the defined center WP of the recess RS and the defined center LP of the semiconductor unit SMU, and the second reference line RL2 may pass through the defined center WP of the recess RS and the defined center QP of the first electromagnetic signal adjusting unit AU1, wherein the acute angle θ1 may be included between the first reference line RL1 and the second reference line RL2. According to the present variant embodiment, the acute angle θ1 may be greater than or equal to 0 degree and less than or equal to 50 degrees (that is, 0°≤θ1≤50°). When the acute angle θ1 is 0 degree, the defined center QP may be located on the same straight light as the defined center WP and the defined center LP, and the defined center QP may be located between the defined center WP and the defined center LP (as shown in FIG. 7B) or located at a side of the defined center WP opposite to the defined center LP (as shown in FIG. 7A). For example, FIG. 7B shows the condition that the acute angle θ1 between the first reference line RL1 and the second reference line RL2 is 0 degree. When the acute angle θ1 is greater than 0 degree, the defined center QP is not located on the straight line (that is, the first reference line RL1) connecting the defined center WP and the defined center LP. According to the above-mentioned range of the acute angle θ1, the defined center QP of the first electromagnetic signal adjusting unit AU1 may be located in the region RG′, wherein the region RG′ may be defined by the circular region RG and the two reference lines which pass through the defined center WP and respectively have the acute angle θ1 of 50 degrees (that is, the maximum of the acute angle θ1) with the first reference line RL1. The definition of the circular region RG may refer to the content mentioned above, and will not be redundantly described. For example, when the acute angle θ1 shown in FIG. 7C is 50 degrees, the two reference lines passing through the defined center WP and respectively having the acute angle θ1 of 50 degrees with the first reference line RL1 may be the second reference line RL2 and the second reference line RL2′ shown in FIG. 7C, and the region RG′ may include the region enclosed by the first reference line RL1 and the second reference line RL2 in the circular region RG and the region enclosed by the first reference line RL1 and the second reference line RL2′ in the circular region RG. In other words, in the present variant embodiment, the first electromagnetic signal adjusting unit AU1 may be disposed on the semiconductor unit SMU, such that the defined center QP may be located in the region RG′.

In other embodiments of the third embodiment, the acute angle θ1 between the first reference line RL1 and the second reference line RL2 may be greater than or equal to 0 degree and less than or equal to 30 degrees (that is, 0°≤θ1≤30°). In such condition, the region RG′ may be defined by the circular region RG and the two reference lines which pass through the defined center LP and respectively have the acute angle θ1 of 30 degrees with the first reference line RL1, and the defined center QP may be located in the region RG′.

It should be noted that the relation between the positions of the defined center WP, the defined center LP and the defined center QP mentioned above is not limited to the condition that the electronic device ED includes the display device and may be applied to various kinds of the electronic device ED. Specifically, the electronic device ED may include any suitable element serving as the semiconductor unit SMU and the first electromagnetic signal adjusting unit AU1 according to the use or type of the electronic device ED, and the relation between the positions of the defined center LP of the semiconductor unit SMU, the defined center WP of the recess RS and the defined center QP of the first electromagnetic signal adjusting unit AU1 may refer to the contents in the above-mentioned embodiments and variant embodiments.

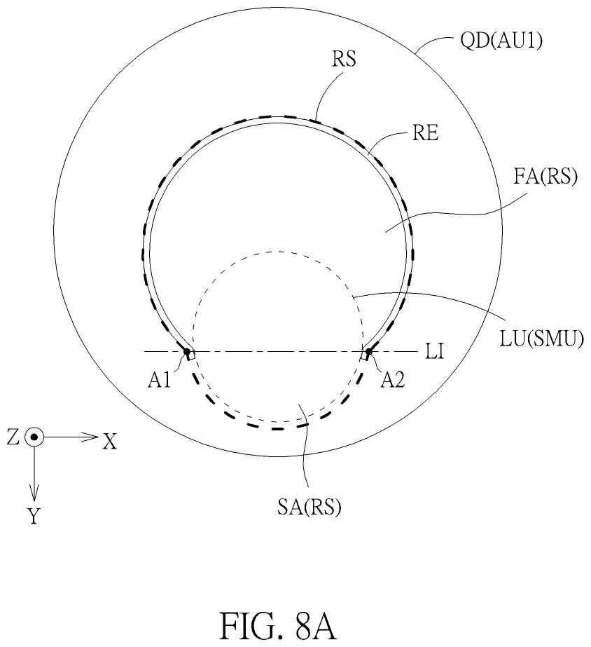

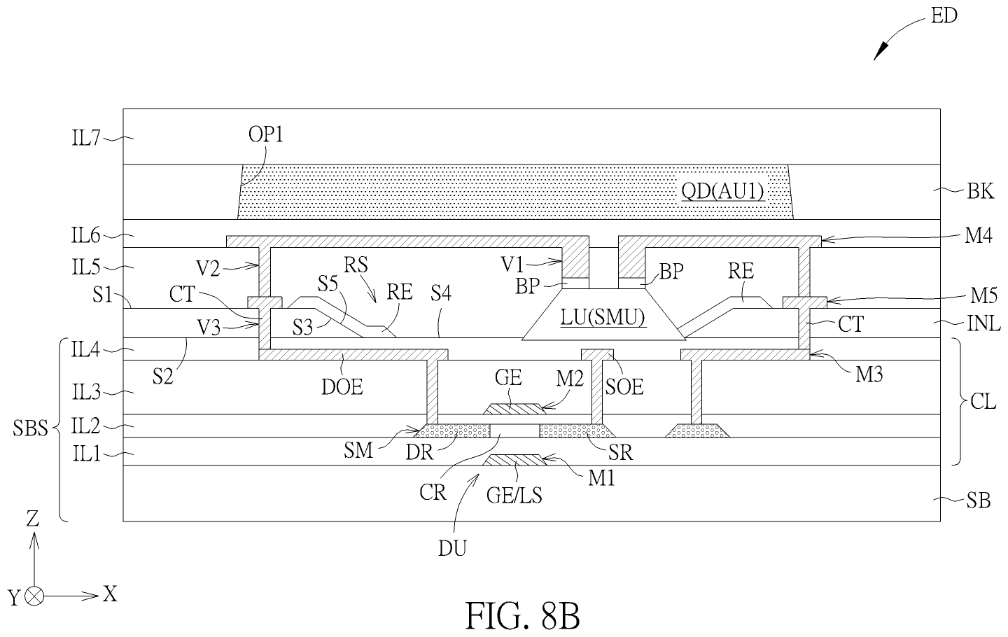

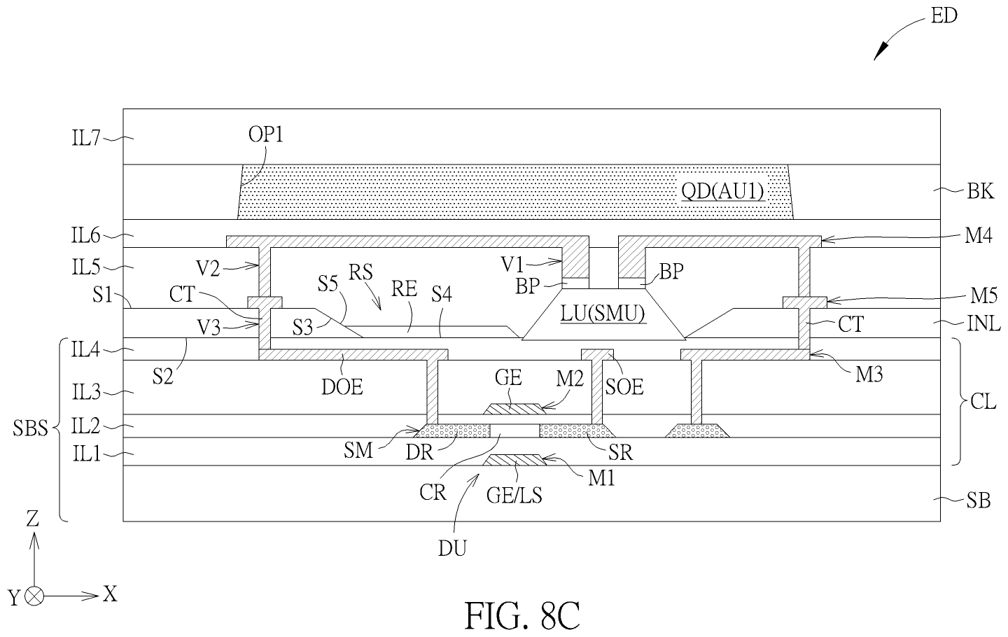

Referring to FIG. 8A, FIG. 8A schematically illustrates a top view of an electronic device according to a fourth embodiment of the present disclosure. The electronic device of the present fourth embodiment may be the display device. Similar to the embodiments shown in FIG. 7A to FIG. 7C, the disposition position of the first electromagnetic signal adjusting unit AU1 (that is, the light adjusting unit QD) of the present fourth embodiment may be determined under the condition that the recess RS is regarded as the main light emitting source, but not limited thereto. In the present embodiment, the electronic device ED may further include an electromagnetic signal reflector RE, wherein the electromagnetic signal reflector RE may be disposed in the recess RS. The electromagnetic signal reflector RE may include any suitable material capable of reflecting electromagnetic signal, according to the type of the element included in the semiconductor unit SMU. For example, the semiconductor unit SMU of the electronic device ED of the present embodiment may include the light emitting unit LU, and the electromagnetic signal reflector RE may include the materials capable of reflecting light, but not limited thereto. In such condition, the electromagnetic signal reflector RE may include metal materials of high reflectivity, such as copper, aluminum, silver, and the like, but not limited thereto. By disposing the electromagnetic signal reflector RE in the recess RS, the overall light emission amount of the recess RS may be improved. The feature of other layers and/or elements of the electronic device ED may refer to the contents mentioned above, and will not be redundantly described.

According to the present embodiment, the electromagnetic signal reflector RE may be disposed at a side of the recess RS away from the semiconductor unit SMU. Specifically, as shown in FIG. 8A, in the top view of the electronic device ED, the edge of the recess RS may have a point A1 and a point A2, wherein the point A1 and the point A2 may be the two points on the portion of the edge of the recess RS contacting or adjacent to the semiconductor unit SMU which can be connected to each other to form the line segment with the maximum length. In other words, a portion of the edge of the recess RS contacting or adjacent to the semiconductor unit SMU may be confirmed at first, and the two points on the portion of the edge of the recess RS which can be connected to each other to form the line segment with the maximum length may respectively be defined as the point A1 and the point A2. In some embodiments, the point A1 and the point A2 may be located at the turning points of the outline of the recess RS where the edge is not smooth or where the shape thereof begins to change, but not limited thereto. After the point P1 and the point P2 are determined, the straight line LI connecting the point A1 and the point A2 may be defined. In the top view of the electronic device ED, the straight line LI may divide the recess RS into a first area FA and a second area SA, wherein the first area FA may include the area further away from the semiconductor unit SMU, and the second area SA may be closer to the semiconductor unit SMU. According to the present embodiment, the electromagnetic signal reflector RE may be disposed in the first area FA of the recess RS, but not limited thereto. “The electromagnetic signal reflector RE may be disposed in the first area FA of the recess RS” mentioned above may represent that the electromagnetic signal reflector RE is disposed on the first surface (that is, the first surface S3 shown in FIG. 1) of the insulating layer INL corresponding to the recess RS in the first area FA and/or the bottom surface S4 (or the upper surface of the insulating layer IL4 shown in FIG. 1) of the recess RS in the first area FA, but not limited thereto. In some embodiments, depending on the process conditions, the electromagnetic signal reflector RE may partially be disposed in the second area SA of the recess RS. By making the electromagnetic signal reflector RE disposed in the recess RS, the light output of the first area FA of the recess RS may be improved, thereby improving the display effect of the electronic device ED. In addition, since the electromagnetic signal reflector RE may not be disposed in the second area SA of the recess RS, the production cost of the electronic device ED may be reduced.

Referring to FIG. 8B, FIG. 8B schematically illustrates a cross-sectional view of an electronic device according to a variant embodiment of the fourth embodiment of the present disclosure. According to the present variant embodiment, the electromagnetic signal reflector RE may be disposed on the side surface S5 of the recess RS and contact the first surface S3 of the insulating layer INL. In such condition, the electromagnetic signal reflector RE may be disposed to surround the semiconductor unit SMU. Therefore, the electromagnetic signal reflector RE may reflect the light emitted from the semiconductor unit SMU (that is, the light emitting unit LU), thereby increasing the light output of the electronic device ED. In some embodiments, the electromagnetic signal reflector RE disposed on the side surface S5 may extend to be on the bottom surface S4 of the recess RS and on the upper surface S1 of the insulating layer INL, but not limited thereto.

In some embodiments, the electromagnetic signal reflector RE may be disposed at a side of the recess RS away from the semiconductor unit SMU, but not at the other side of the recess RS adjacent to the semiconductor unit SMU, for example, as shown in FIG. 8A. In such condition, the electronic device ED may not include the electromagnetic signal reflector RE located at the right side of the recess RS which is shown in FIG. 8B.

Referring to FIG. 8C, FIG. 8C schematically illustrates a cross-sectional view of an electronic device according to another variant embodiment of the fourth embodiment of the present disclosure. According to the present variant embodiment, the electromagnetic signal reflector RE may be disposed on the bottom surface S4 of the recess RS. Specifically, the electromagnetic signal reflector RE may be disposed on the portion of the bottom surface S4 not overlapped with the semiconductor unit SMU. The electromagnetic signal reflector RE may be disposed at a side of the recess RS away from the semiconductor unit SMU. For example, the electromagnetic signal reflector RE may be disposed on the bottom surface S4 of the recess RS in the first area FA (as shown in FIG. 8A), but not limited thereto. By disposing the electromagnetic signal reflector RE on the bottom surface S4 of the recess RS, the electromagnetic signal reflector RE may reflect the light emitted downward from the semiconductor unit SMU, thereby increasing the light output of the electronic device ED. In some embodiments, the electromagnetic signal reflector RE may further be disposed to surround the side surface S5 of the recess RS (corresponding to the first surface S3 of the insulating layer INL) in addition to being disposed on the bottom surface S4 of the recess RS, as shown in FIG. 8B.

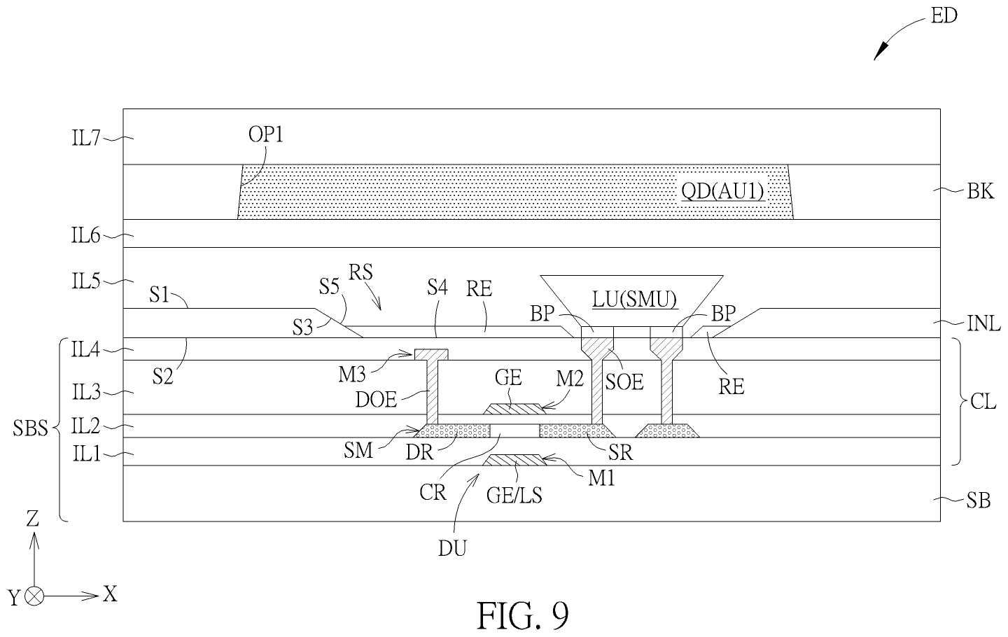

Referring to FIG. 9, FIG. 9 schematically illustrates a cross-sectional view of an electronic device according to a fifth embodiment of the present disclosure. According to the present embodiment, as shown in FIG. 9, the semiconductor unit SMU of the electronic device ED may be disposed in a flip chip way. In such condition, the conductive pads BP of the semiconductor unit SMU may be located on the substrate structure SBS and be electrically structure the connected to the substrate SBS. Therefore, semiconductor unit SMU may directly be electrically connected to the driving unit DU through the conductive pads BP. In other words, compared with the electronic devices ED above, the electronic device ED shown in FIG. 9 may not include the conductive layer M4 and the connecting element CT that penetrate the insulating layer INL, but not limited thereto. The electronic device ED of the present embodiment may further include the electromagnetic signal reflector RE, wherein the electromagnetic signal reflector RE may be disposed on the bottom surface S4 of the recess RS. Therefore, the electromagnetic signal reflector RE may reflect the light emitted downward from the semiconductor unit SMU, thereby increasing the light output of the electronic device ED.

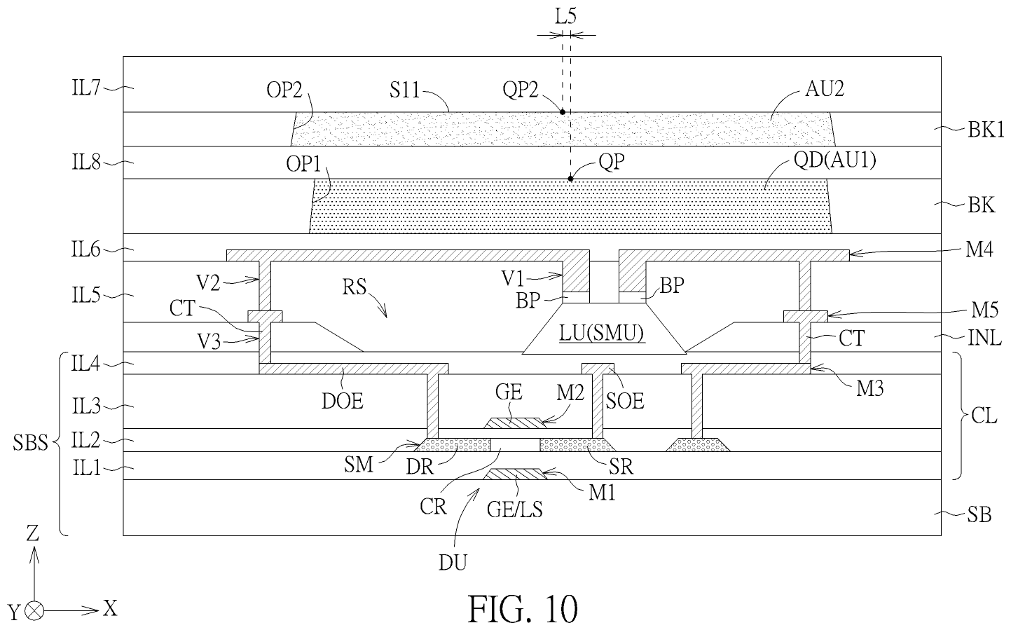

Referring to FIG. 10, FIG. 10 schematically illustrates a cross-sectional view of an electronic device according to a sixth embodiment of the present disclosure. According to the present embodiment, the electronic device ED may further include a second electromagnetic signal adjusting unit AU2 disposed on the first electromagnetic signal adjusting unit AU1. Specifically, as shown in FIG. 10, the electronic device ED may further include an insulating layer IL8 and a shielding structure BK1 disposed on the first electromagnetic signal adjusting unit AU1, wherein the shielding structure BK1 may define the opening OP2, and the second electromagnetic signal adjusting unit AU2 may be disposed in the opening OP2. The first electromagnetic signal adjusting unit AU1 and the second electromagnetic signal adjusting unit AU2 may include any suitable element capable of adjusting electromagnetic signal according to the use or type of the electronic device ED. For example, the electronic device ED of the present embodiment may include the display device, the first electromagnetic signal adjusting unit AU1 may include quantum dot material, and the second electromagnetic signal adjusting unit AU2 may include color filter material, but not limited thereto. In such condition, the shielding structure BK1 may for example include black matrix (BM).

As shown in FIG. 10, as mentioned above, the second electromagnetic signal adjusting unit AU2 may have a defined center QP2. In the top view of the electronic device ED, the defined center QP2 of the second electromagnetic signal adjusting unit AU2 may be the center (not shown) of the minimum virtual rectangle that surrounds the second electromagnetic signal adjusting unit AU2, but not limited thereto. In the cross-sectional view of the electronic device ED, the defined center QP2 of the second electromagnetic signal adjusting unit AU2 may for example be the midpoint of the upper surface S11 of the second electromagnetic signal adjusting unit AU2. The definition of the defined center QP of the first electromagnetic signal adjusting unit AU1 may refer to the contents above, and will not be redundantly described. According to the present embodiment, the second electromagnetic signal adjusting unit AU2 may be disposed on the first electromagnetic signal adjusting unit AU1, such that the defined center QP2 of the second electromagnetic signal adjusting unit AU2 may be corresponding to or adjacent to the defined center QP of the first electromagnetic signal adjusting unit AU1. Specifically, as shown in FIG. 10, a distance L5 may be between the defined center QP2 of the second electromagnetic signal adjusting unit AU2 and the defined center QP of the first electromagnetic signal adjusting unit AU1, wherein the distance L5 may be greater than or equal to 0 micrometer and less than or equal to 15 micrometers, but not limited thereto. In some embodiments, the distance L5 may be greater than or equal to 0 micrometer and less than or equal to 7 micrometers. For example, when the distance L5 is 0 micrometer, the defined center QP2 may overlap the defined center QP in the top view of the electronic device ED, and the second electromagnetic signal adjusting unit AU2 may correspond to the first electromagnetic signal adjusting unit AU1. Through the above-mentioned design, the second electromagnetic signal adjusting unit AU2 may substantially match the first electromagnetic signal adjusting unit AU1, such that the light converted by the first electromagnetic signal adjusting unit AU1 (including quantum dot material) may pass through the second electromagnetic signal adjusting unit AU2 (including color filter material), and the portion of the light not converted by the first electromagnetic signal adjusting unit AU1 may be filtered out by the second electromagnetic signal adjusting unit AU2. In addition, the second electromagnetic signal adjusting unit AU2 may be used to reduce interference of ambient light on the electronic device ED. In the present embodiment, the size of the second electromagnetic signal adjusting unit AU2 may be greater than or equal to the size of the first electromagnetic signal adjusting unit AU1. For example, in the top view of the electronic device ED, the area of the second electromagnetic signal adjusting unit AU2 may be greater than or equal to the area of the first electromagnetic signal adjusting unit AU1, but not limited thereto.

Since the defined center QP2 of the second electromagnetic signal adjusting unit AU2 may substantially correspond to the defined center QP of the first electromagnetic signal adjusting unit AU1, when the first electromagnetic signal adjusting unit AU1 and/or the second electromagnetic signal adjusting unit AU2 is disposed under the condition that the semiconductor unit SMU (that is, the light emitting unit LU) is regarded as the main light emitting source, the distance between the defined center QP2 of the second electromagnetic signal adjusting unit AU2 and the defined center LP of the semiconductor unit SMU may substantially be equal to the distance L2 between the defined center QP and the defined center LP above; and when the first electromagnetic signal adjusting unit AU1 and/or the second electromagnetic signal adjusting unit AU2 is disposed under the condition that the recess RS is regarded as the main light emitting source, the distance between the defined center QP2 of the second electromagnetic signal adjusting unit AU2 and the defined center WP of the recess RS may substantially be equal to the distance L4 between the defined center QP and the defined center WP above. Therefore, the relation between the positions of the defined center QP2, the defined center LP and the defined center WP may refer to the contents mentioned above, and will not be redundantly described.

The relation between the positions of the defined center QP of the first electromagnetic signal adjusting unit AU1, the defined center LP of the semiconductor unit SMU, and the defined center WP of the recess RS will be detailed in the following by taking the antenna device as an example of the electronic device ED.

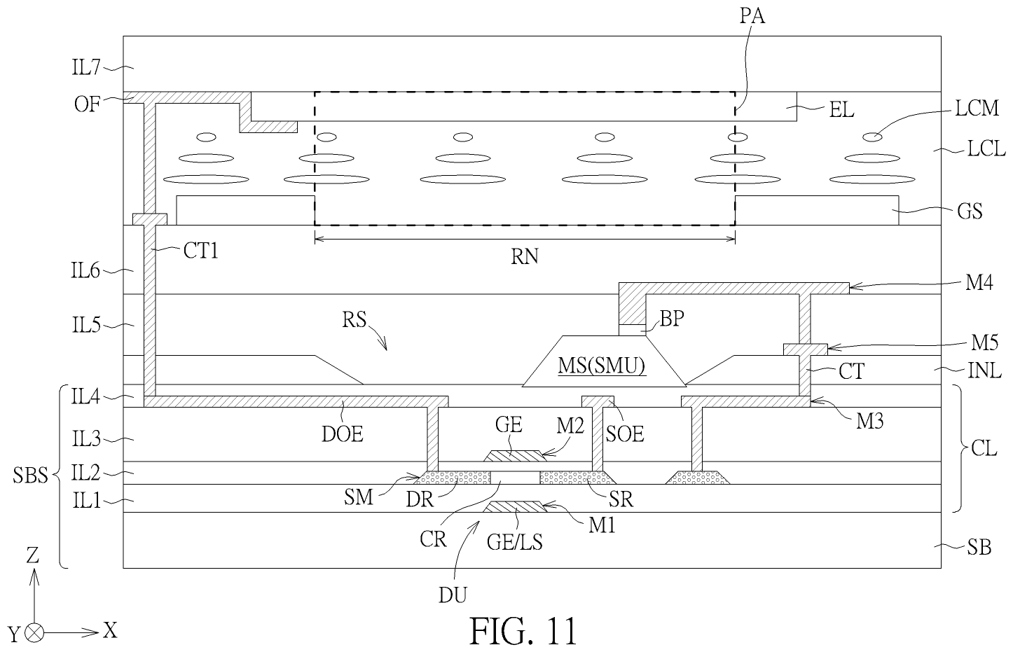

Referring to FIG. 11, FIG. 11 schematically illustrates a cross-sectional view of an electronic device according to a seventh embodiment of the present disclosure. According to the present embodiment, the electronic device ED may include an antenna device, such as a liquid crystal antenna, but not limited thereto. In such condition, the semiconductor unit SMU of the electronic device ED may include any suitable element capable of receiving/transmitting micro wave signal. For example, the semiconductor unit SMU of the present embodiment may include a microstrip MS, but not limited thereto. The microstrip MS may be disposed in the recess RS and located at a side of the recess RS. The conductive pads BP of the microstrip MS may be electrically connected to the driving unit DU through the conductive layer M4 and the connecting element CT, but not limited thereto. In addition, the first electromagnetic signal adjusting unit AU1 of the electronic device ED may include the phase adjusting unit PA, but not limited thereto. Specifically, the electronic device ED may include a liquid crystal layer LCL and an electrode EL disposed between the insulating layer IL6 and the insulating layer IL7, where the electrode EL and the liquid crystal layer LCL may form the phase adjusting unit PA, that is, the first electromagnetic signal adjusting unit AU1. The electronic device ED may further include a ground strip GS disposed between the insulating layer IL6 and the insulating layer IL7, and the structure of the phase adjusting unit PA may for example be defined through the disposition position of the ground strip GS. Specifically, in the cross-sectional view of the electronic device ED, the phase adjusting unit PA may be defined as the structure formed by a portion of the electrode EL corresponding to the region RN between adjacent two ground strips GS and a portion of the liquid crystal layer LCL corresponding to the region RN, but not limited thereto. In some embodiments, the electrode EL may be disposed on the surface of the insulating layer IL7 adjacent to the liquid crystal layer LCL. The liquid crystal layer LCL may include liquid crystal molecules LCM. The electronic device ED may further include an offset line OF, and the electrode EL may be electrically connected to the driving unit DU through the offset line OF and the connecting element CT1. The connecting element CT1 may penetrate the insulating layer IL6, the insulating layer IL5, the insulating layer INL and the insulating layer IL4 to be electrically connected to the source electrode SOE or the drain electrode DOE of the driving unit DU. In detail, the driving unit DU may provide a voltage to the electrode EL through the offset line OF, the ground strip GS may provide a common voltage (for example, grounded), and the liquid crystal molecules LCM in the liquid crystal layer LCL may be affected by the electric field formed by the voltage difference between the electrode EL and the ground strip GS, such that the dielectric coefficient of the liquid crystal layer LCL is changed, and the phase of the micro wave passing through the liquid crystal layer LCL is thereby changed, thereby achieving the function of adjusting the phase of micro wave. It should be noted that the structure of the electronic device ED shown in FIG. 11 is exemplary, and the present disclosure is not limited thereto.

In some embodiments, the disposition position of the first electromagnetic signal adjusting unit AU1 (that is, the phase adjusting unit PA) may be determined under the condition that the semiconductor unit SMU (that is, the microstrip MS) is regarded as the main signal receiving source and/or the main signal transmitting source. Therefore, in the top view of the electronic device ED, the phase adjusting unit PA may cover (or overlap) the microstrip MS. In such condition, the defined center QP of the first electromagnetic signal adjusting unit AU1 mentioned above may be the defined center of the phase adjusting unit PA, the defined center LP of the semiconductor unit SMU mentioned above may be the defined center of the microstrip MS, and the relation between the positions of the defined center of the phase adjusting unit PA, the defined center of the recess RS and the defined center of the microstrip MS may refer to FIG. 6A to FIG. 6C and related descriptions above, which will not be redundantly described.

In some embodiments, the disposition position of the first electromagnetic signal adjusting unit AU1 (that is, the phase adjusting unit PA) may be determined under the condition that the recess RS is regarded as the main signal receiving source and/or the main signal transmitting source. Therefore, in the top view of the electronic device ED, the phase adjusting unit PA may cover (or overlap) the recess RS and the microstrip MS. In such condition, the defined center QP of the first electromagnetic signal adjusting unit AU1 mentioned above may be the defined center of the phase adjusting unit PA, the defined center LP of the semiconductor unit SMU mentioned above may be the defined center of the microstrip MS, and the relation between the positions of the defined center of the phase adjusting unit PA, the defined center of the recess RS and the defined center of the microstrip MS may refer to FIG. 7A to FIG. 7C and related descriptions above, which will not be redundantly described.

Through the position design of the defined center of the phase adjusting unit PA, the defined center of the recess RS and the defined center of the microstrip MS, the accuracy of phase adjustment of the phase adjusting unit PA may be improved, or the size of the phase adjusting unit PA may be reduced.

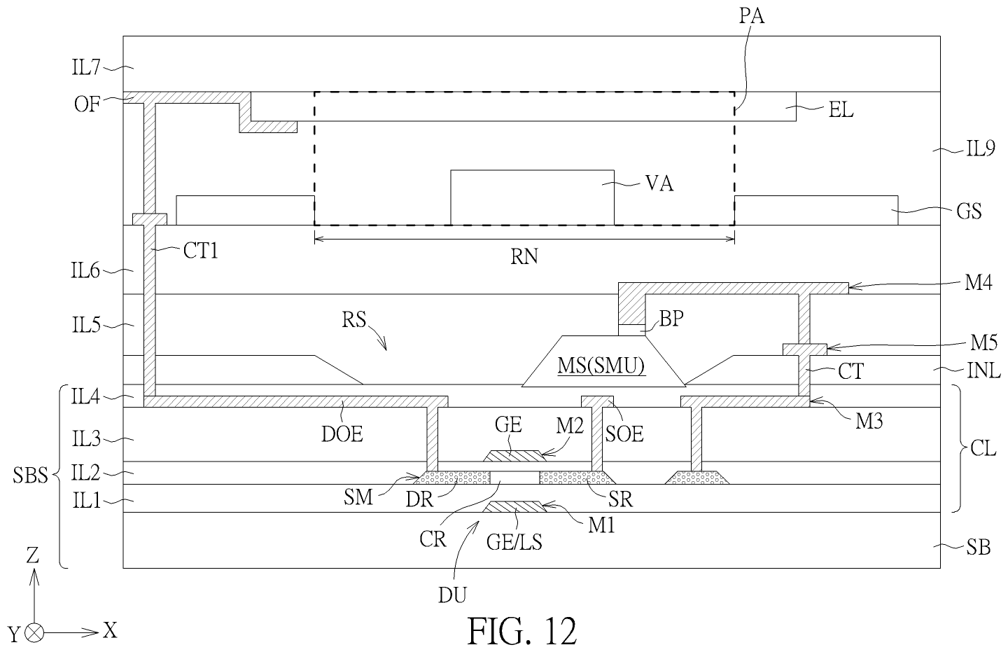

Referring to FIG. 12, FIG. 12 schematically illustrates a cross-sectional view of an electronic device according to an eighth embodiment of the present disclosure. The electronic device ED of the present embodiment may include the antenna device. One of the main differences between the electronic device ED of the present embodiment and the electronic device ED shown in FIG. 11 is the structure of the phase adjusting unit PA. Specifically, the phase adjusting unit PA of the present embodiment may be formed by the electrode EL and a varactor VA. The varactor VA may include varactor diode, but not limited thereto. In detail, as shown in FIG. 12, the electronic device ED may include the ground strip GS, the varactor VA, the electrode EL, the insulating layer IL9 and the offset line OF disposed between the insulating layer IL6 and the insulating layer IL7, wherein the electrode EL and the varactor VA may form the phase adjusting unit PA, that is, the first electromagnetic signal adjusting unit AU1. The insulating layer IL9 may cover the ground strip GS and the varactor VA. The structure of the phase adjusting unit PA may be defined through the disposition position of the ground strip GS. Specifically, in the cross-sectional view of the electronic device ED, the phase adjusting unit PA may be defined as the structure formed by a portion of the electrode EL corresponding to the region RN between adjacent two ground strips GS, a portion of the insulating layer IL9 corresponding to the region RN, and the varactor VA, but not limited thereto. In detail, the driving unit DU may provide a voltage to the electrode EL through the offset line OF, the ground strip GS may provide a common voltage (for example, grounded), and the varactor VA may adjust the capacitance thereof through voltage change, such that the frequency of the electromagnetic signal passing through the varactor VA may be adjusted, thereby achieving the function of adjusting phase. The feature of other elements and/or layers of the electronic device ED may refer to the contents mentioned above, and will not be redundantly described. In addition, the relation between the positions of the defined center of the phase adjusting unit PA, the defined center of the recess RS and the defined center of the microstrip MS may refer to FIG. 11 and related descriptions. It should be noted that the structure of the electronic device ED shown in FIG. 12 is exemplary, and the present disclosure is not limited thereto.

The relation between the positions of the defined center QP of the first electromagnetic signal adjusting unit AU1, the defined center LP of the semiconductor unit SMU, and the defined center WP of the recess RS will be detailed in the following by taking the sensing device as an example of the electronic device ED.

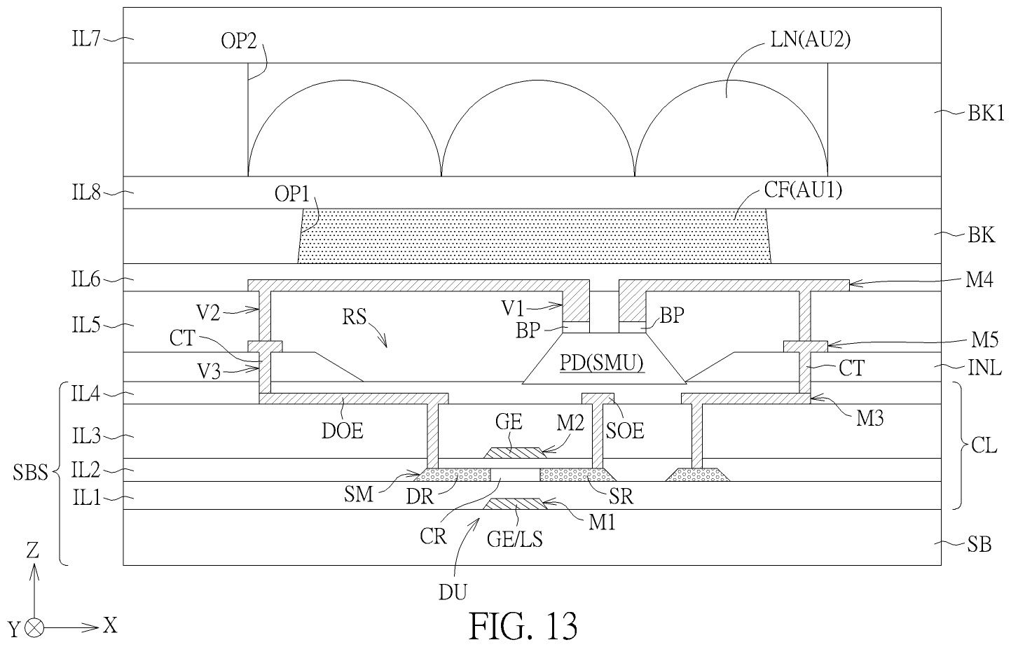

Referring to FIG. 13, FIG. 13 schematically illustrates a cross-sectional view of an electronic device according to a ninth embodiment of the present disclosure. The electronic device ED of the present embodiment may include a sensing device, such as a light sensing device, but not limited thereto. In such condition, the semiconductor unit SMU of the electronic device ED may include any suitable element capable of receiving light signal. For example, the semiconductor unit SMU may include a photo diode PD, but not limited thereto. In some embodiments, the semiconductor unit SMU may include other suitable light sensing elements. In addition, the first electromagnetic signal adjusting unit AU1 of the electronic device ED may include a light filtering element CF, but not limited thereto. For example, the first electromagnetic signal adjusting unit AU1 may include color filter material, and the shielding structure BK may include a black matrix, but not limited thereto. In some embodiments, the first electromagnetic signal adjusting unit AU1 may include a bandpass filter. As shown in FIG. 13, in the cross-sectional view of the electronic device ED, the photo diode PD may be disposed in the recess RS and located at a side of the recess RS, and the light filtering element CF may cover the photo diode PD, such that the light may pass through the light filtering element CF before entering the photo diode PD. Specifically, the light may enter from a side of the insulating layer IL7 of the electronic device ED opposite to the photo diode PD and be received by the photo diode PD after passing through the light filtering element CF. In such condition, the insulating layer IL7 may include any suitable insulating material of high transmittance.

In some embodiments, the electronic device ED may serve as a biosensor. For example, the semiconductor unit SMU may include the photo diode PD, and the first electromagnetic signal adjusting unit AU1 may include the light filtering element CF, wherein the red light (or the light with a wavelength close to 660 nanometers (nm)) may pass through the light filtering element CF and enter the photo diode PD, such that the electronic device ED may be used to detect blood oxygen or biological features. In some embodiments, the electronic device ED may serve as the fingerprint recognition device. In some embodiments, the electronic device ED may serve as the X-ray machine. In some embodiments, the electronic device ED may include other suitable light sensing devices, such as camera, but not limited thereto.

Similarly, the definitions and the relation between the positions of the defined center of the first electromagnetic signal adjusting unit AU1 (such as the light filtering element CF), the defined center of the recess RS and the defined center of the semiconductor unit SMU (such as the photo diode PD) of the present embodiment may refer to FIG. 4 to FIG. 7C and related descriptions above, which will not be redundantly described. Through the design above, the area of the first electromagnetic signal adjusting unit AU1 overlapped with the semiconductor unit SMU or the proportion of the first electromagnetic signal adjusting unit AU1 overlapped with the semiconductor unit SMU may increase under the condition that the first electromagnetic signal adjusting unit AU1 overlaps the semiconductor unit SMU, thereby improving the light emitting efficiency of the electronic device ED or reducing the size of the first electromagnetic signal adjusting unit AU1.

In addition, the electronic device ED of the present embodiment may further include the second electromagnetic signal adjusting unit AU2 disposed on the first electromagnetic signal adjusting unit AU1. Specifically, the electronic device ED may include the shielding structure BK1 disposed on the insulating layer IL8, the shielding structure BK1 may define the opening OP2, and the second electromagnetic signal adjusting unit AU2 may be disposed in the opening OP2. In the present embodiment, the second electromagnetic signal adjusting unit AU2 may include microlens LN for converting incident light of various angles into more collimated light, but not limited thereto. In such condition, the amount of light entering the photo diode PD may be increased through the microlens LN, thereby improving the accuracy of sensing function of the electronic device ED. In the top view of the electronic device ED, the second electromagnetic signal adjusting unit AU2 may cover the first electromagnetic signal adjusting unit AU1 and the semiconductor unit SMU. The relation between the positions of the second electromagnetic signal adjusting unit AU2 and the first electromagnetic signal adjusting unit AU1 of the present embodiment may refer to FIG. 10 and related descriptions above, and will not be redundantly described. It should be noted that the first electromagnetic signal adjusting unit AU1 and the second electromagnetic signal adjusting unit AU2 may include any suitable element according to the type or use of the electronic device ED.

In summary, an electronic device is provided by the present disclosure, wherein the electronic device includes semiconductor units disposed in recesses and first electromagnetic signal adjusting units disposed on the semiconductor units. Each of the semiconductor units may be disposed at a side of the recess, such that the semiconductor units of the electronic device may be disposed in order. Therefore, the difficulty of the bonding process of the semiconductor units may be reduced, or the performance of the electronic device may be improved. In addition, through the design of the relation between the positions of the defined center of the semiconductor unit, the defined center of the recess and the defined center of the first electromagnetic signal adjusting unit, the area of the first electromagnetic signal adjusting unit overlapped with the semiconductor unit or the proportion of the first electromagnetic signal adjusting unit overlapped with the semiconductor unit may increase under the condition that the first electromagnetic signal adjusting unit covers the semiconductor unit, thereby improving the light emitting efficiency of the electronic device or reducing the size of the first electromagnetic signal adjusting unit.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate structure;
an insulating layer disposed on the substrate structure and having a recess;
a semiconductor unit disposed in the recess; and
a first electromagnetic signal adjusting unit disposed on the insulating layer and configured for adjusting an electromagnetic signal, wherein the first electromagnetic signal adjusting unit is overlapped with the semiconductor unit;
wherein in a top view of the electronic device, a first distance is between a defined center of the recess and a defined center of the semiconductor unit, a second distance is between a defined center of the first electromagnetic signal adjusting unit and the defined center of the semiconductor unit, and the first distance is greater than 0 micrometer and the second distance is less than or equal to the first distance.

2. The electronic device as claimed in claim 1, further comprising a second electromagnetic signal adjusting unit disposed on the first electromagnetic signal adjusting unit and overlapped with the semiconductor unit, wherein in the top view of the electronic device, a third distance is between a defined center of the second electromagnetic signal adjusting unit and the defined center of the first electromagnetic signal adjusting unit, and the third distance is greater than or equal to 0 micrometer and less than or equal to 15 micrometers.

3. The electronic device as claimed in claim 2, wherein the third distance is greater than or equal to 0 micrometer and less than or equal to 7 micrometers.

4. The electronic device as claimed in claim 1, wherein in the top view of the electronic device, a first reference line is passing through the defined center of the recess and the defined center of the semiconductor unit, a second reference line is passing through the defined center of the first electromagnetic signal adjusting unit and the defined center of the semiconductor unit, and an acute angle between the first reference line and the second reference line is greater than or equal to 0 degree and less than or equal to 45 degrees.

5. The electronic device as claimed in claim 4, wherein the acute angle is greater than or equal to 0 degree and less than or equal to 25 degrees.

6. The electronic device as claimed in claim 1, wherein a fourth distance between the defined center of the first electromagnetic signal adjusting unit and the defined center of the recess is greater than 0 and less than or equal to the first distance.

7. The electronic device as claimed in claim 1, wherein in the top view of the electronic device, the recess is partially overlapped with the first electromagnetic signal adjusting unit.

8. The electronic device as claimed in claim 1, wherein the semiconductor unit comprises a light emitting diode.

9. The electronic device as claimed in claim 8, wherein the first electromagnetic signal adjusting unit comprises quantum dot material.

10. The electronic device as claimed in claim 1, wherein the semiconductor unit comprises a photodiode.

11. The electronic device as claimed in claim 10, wherein the first electromagnetic signal adjusting unit comprises color filter material.

12. An electronic device, comprising:
a substrate structure;
an insulating layer disposed on the substrate structure and having a recess;
an electromagnetic signal reflector disposed in the recess;
a semiconductor unit disposed in the recess; and
a first electromagnetic signal adjusting unit disposed on the insulating layer and configured for adjusting an electromagnetic signal, wherein the first electromagnetic signal adjusting unit is overlapped with the semiconductor unit;
wherein in a top view of the electronic device, a first distance is between a defined center of the semiconductor unit and a defined center of the recess, a second distance is between a defined center of the first electromagnetic signal adjusting unit and the defined center of the recess, and the first distance is greater than 0 micrometer and the second distance is less than or equal to the first distance.

13. The electronic device as claimed in claim 12, wherein the electromagnetic signal reflector is disposed on a side surface of the recess.

14. The electronic device as claimed in claim 12, wherein the electromagnetic signal reflector is disposed on a bottom surface of the recess.

15. The electronic device as claimed in claim 12, further comprising a second electromagnetic signal adjusting unit disposed on the first electromagnetic signal adjusting unit, wherein in the top view of the electronic device, a third distance is between a defined center of the second electromagnetic signal adjusting unit and the defined center of the first electromagnetic signal adjusting unit, and the third distance is greater than or equal to 0 micrometer and less than or equal to 15 micrometers.

16. The electronic device as claimed in claim 15, wherein the third distance is greater than or equal to 0 micrometer and less than or equal to 7 micrometers.

17. The electronic device as claimed in claim 12, wherein in the top view of the electronic device, a first reference line is passing through the defined center of the recess and the defined center of the semiconductor unit, a second reference line is passing through the defined center of the recess and the defined center of the first electromagnetic signal adjusting unit, and an acute angle between the first reference line and the second reference line is greater than or equal to 0 degree and less than or equal to 50 degrees.

18. The electronic device as claimed in claim 17, wherein the acute angle is greater than or equal to 0 degree and less than or equal to 30 degrees.

19. The electronic device as claimed in claim 12, wherein the semiconductor unit comprises a light emitting diode.

20. The electronic device as claimed in claim 19, wherein the first electromagnetic signal adjusting unit comprises quantum dot material.
